(19) United States
(12) Patent Application Publication
(10) Pub. No.: US 2024/0324380 A1
(43) Pub. Date: Sep. 26, 2024

(54) Touch Structure, Display Substrate, and Display Panel

(71) Applicant: BOE TECHNOLOGY GROUP CO., LTD., Chaoyang District, Beijing (CN)

(72) Inventors: Xuefei Sun, Beijing (CN); Xinxing Wang, Beijing (CN); Kuanjun Peng, Beijing (CN); Jaegeon You, Beijing (CN); Yingtao Wang, Beijing (CN); Qian Jia, Beijing (CN); Liyan Liu, Beijing (CN); Honghui Lin, Beijing (CN)

(21) Appl. No.: 18/580,250

(22) PCT Filed: Sep. 21, 2022
(86) PCT No.: PCT/CN2022/120314

§ 371 Date: Jan. 18, 2024

(30) Foreign Application Priority Data
Oct. 27, 2021 (CN) 202111256548.9

(51) Int. Cl. H10K 59/35; G06F 3/041; G06F 3/044; H10K 59/122; H10K 59/40

(52) U.S. Cl. CPC H10K 59/353; G06F 3/0412; G06F 3/044; H10K 59/122; H10K 59/40; G06F 2203/04112

(57) ABSTRACT

A touch structure includes a metal mesh including a plurality of metal conductive lines. The metal mesh has a plurality of openings, each opening is enclosed by metal conductive lines, and a shape of each opening is asymmetric.

### CROSS-REFERENCE TO RELATED APPLICATIONS

This application is the United States national phase of International Patent Application No. PCT/CN2022/120314, filed Sep. 21, 2022, and claims priority to Chinese Patent Application No. 202111256548.9, filed Oct. 27, 2021, the disclosures of which are hereby incorporated by reference in their entireties.

### BACKGROUND OF THE INVENTION

### Field of the Invention

The present disclosure relates to the field of display technologies, and in particular, to a touch structure, a display substrate, and a display panel.

### Description of Related Art

With the continuous development of electronic products, display panels with touch control functions and display functions can realize simple and flexible human-computer interaction and are therefore widely used. The structures of touch display panels include, for example, one glass solution (OGS) display panels, on-cell display panels, and in-cell display panels.

### SUMMARY OF THE INVENTION

In an aspect, a touch structure is provided, including: a metal mesh including a plurality of metal conductive lines. The metal mesh has a plurality of openings, each opening is enclosed by metal conductive lines, and a shape of each opening is asymmetric.

In some embodiments, the opening is enclosed by N metal conductive lines that are connected end to end, and the N metal conductive lines have M different extension directions, N and M being integers, N≥5, and 3≤M≤N.

In some embodiments, any two metal conductive lines among the N metal conductive lines are asymmetrical to each other.

In some embodiments, the metal mesh includes at least one type of opening, each type of opening includes a plurality of openings with the same shape, and different types of openings have different shapes.

In some embodiments, the metal mesh includes a plurality of opening units, each opening unit including one or more openings, and at least one opening in the opening unit is enclosed by more than 8 metal conductive lines that are connected end to end.

In some embodiments, the opening unit includes at least three openings, and the at least three openings in the opening unit have different shapes and/or different areas.

In some embodiments, shapes of the metal conductive lines include a straight line segment and/or a curved line segment.

In some embodiments, the shape of the opening includes at least one outwardly protruding convex angle and/or at least one inwardly protruding concave angle.

In some embodiments, a width of a metal conductive line is in a range from 1 μm to 20 μm.

In some embodiments, the metal conductive lines are made of copper, silver, nanocarbon or graphene.

In some embodiments, the touch structure includes a plurality of touch electrodes, each touch electrode includes a metal mesh, and the plurality of touch electrodes are configured to be independently connected to a touch chip.

In some embodiments, the touch structure includes a plurality of driving units and a plurality of sensing units that are insulated from each other; each driving unit includes a plurality of driving electrodes arranged side by side along a first direction and a first connection portion that electrically connects two adjacent driving electrodes; each sensing unit includes a plurality of sensing electrodes arranged side by side along a second direction and a second connection portion that electrically connects two adjacent sensing electrodes, the first direction and the second direction intersecting.

The touch structure includes a first metal layer, an insulating layer and a second metal layer that are stacked in sequence. The insulating layer is provided therein with a plurality of via holes; the driving electrodes, the first connection portion and the sensing electrodes are located in one of the first metal layer and the second metal layer, the second connection portion is located in another of the first metal layer and the second metal layer, and the second connection portion electrically connects the two adjacent sensing electrodes through via holes; or, the driving electrodes, the second connection portion and the sensing electrodes are located in one of the first metal layer and the second metal layer, and the first connection portion is located in another of the first metal layer and the second metal layer, and the first connection portion electrically connects the two adjacent driving electrodes through via holes.

The driving electrodes, the sensing electrodes, the first connection portion and the second connection portion each include a metal mesh.

In some embodiments, an area of a driving electrode and/or an area of a sensing electrode is in a range from 9 mm² to 25 mm².

In another aspect, a display substrate is provided, including: a base and a display functional layer. The display functional layer is disposed on the base, the display functional layer includes a plurality of sub-pixels, and a shape of a light-emitting region of each sub-pixel is asymmetric.

In some embodiments, a contour of the light-emitting region is enclosed by N edges that are connected end to end, and the N edges have M different extension directions; N and M being integers, N≥5, and 3≤M≤N.

In some embodiments, any two edges among the N edges are asymmetrical to each other.

In some embodiments, the display functional layer includes the sub-pixels of a plurality of colors, and a contour of a light-emitting region of a sub-pixel of at least one color is composed of more than 8 edges that are connected end to end.

In some embodiments, light-emitting regions of sub-pixels of different colors have different shapes and/or different areas.

In some embodiments, the display functional layer includes a pixel definition layer provided therein with a plurality of light exit openings, each light exit opening determines a light-emitting region of a sub-pixel, and a shape of the light exit opening is substantially the same as the shape of the light-emitting region of the sub-pixel.

In some embodiments, the display functional layer includes a blue sub-pixel, a red sub-pixel and a green sub-pixel; an area of a light-emitting region of the blue sub-pixel is greater than an area of a light-emitting region of the red sub-pixel, and the area of the light-emitting region of the red sub-pixel is greater than an area of a light-emitting region of the green sub-pixel. The pixel definition layer includes a first light exit opening, a second light exit opening and a third light exit opening; the first light exit opening is configured to determine the light-emitting region of the blue sub-pixel, and the second light exit opening is configured to determine the light-emitting region of the red sub-pixel, and the third light exit opening is configured to determine the light-emitting region of the green sub-pixel; an opening area of the first light exit opening is greater than an opening area of the second light exit opening, and the opening area of the second light exit opening is greater than an opening area of the third light exit opening.

In yet another aspect, a display panel is provided, including: the display substrate as described above and the touch structure as described above. The touch structure is disposed on a light exit side of the display substrate.

In some embodiments, an orthogonal projection of a light-emitting region of at least one sub-pixel of the display substrate on the base of the display substrate is located within an orthogonal projection of an opening of the metal mesh of the touch structure on the base of the display substrate.

In some embodiments, an orthogonal projection of the light-emitting region of each sub-pixel on the base is located within an orthogonal projection of an opening of the metal mesh on the base.

In some embodiments, a contour of the orthogonal projection of the light-emitting region of the at least one sub-pixel on the base and a contour of the orthogonal projection of the opening on the base have a gap therebetween.

In some embodiments, the display substrate includes a plurality of pixel units, and each pixel unit includes a plurality of sub-pixels; the metal mesh includes a plurality of opening units, and each opening unit includes one or more openings; and orthogonal projections of light-emitting regions of a plurality of sub-pixels of a pixel unit on the base are located within orthogonal projections of one or more openings of an opening unit on the base.

In some embodiments, the pixel unit includes a plurality of sub-pixel, and the opening unit includes one opening; orthogonal projections of the plurality of sub-pixels in the pixel unit on the base are located within an orthogonal projection of the one opening on the base. Alternatively, the pixel unit includes a plurality of sub-pixels, and the opening unit includes two openings; an orthogonal projection of a light-emitting region of at least one sub-pixel in the pixel unit on the base is located within an orthogonal projection of one of the two openings on the base; and an orthogonal projection of a light-emitting region of a remaining sub-pixel on the base is located within an orthogonal projection of another of the two openings on the base.

In some embodiments, the pixel unit includes sub-pixels of X colors, the opening unit includes openings of X shapes, and the sub-pixels of X colors and the openings of X shapes are in one-to-one correspondence, X being an integer and X≥3; a first orthogonal projection of an opening of a target shape on the base covers a second orthogonal projection of a light-emitting region of a sub-pixel of a target color on the base; the target shape is any one of the X shapes, and the target color is a color corresponding to the target shape; and a shape of the first orthogonal projection is substantially the same as a shape of the second orthogonal projection, and a contour of the second orthogonal projection and a contour of the first orthogonal projection have a gap therebetween.

In some embodiments, a vertical distance between the contour of the first orthogonal projection and the contour of the second orthogonal projection is in a range from 8 μm to 12 μm.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a top view of a metal mesh, in accordance with some embodiments;

FIG. 2A is a diagram showing a reflection light path of a symmetrical opening;

FIG. 2B is a diagram showing a reflection light path of an asymmetric opening;

FIG. 3 is a top view of openings, in accordance with some embodiments;

FIG. 4 is a top view of openings, in accordance with some other embodiments;

FIG. 5 is a top view of another opening, in accordance with some embodiments;

FIG. 6 is a top view of touch electrodes, in accordance with some embodiments;

FIG. 7 is an enlarged view of border regions of two touch electrodes, in accordance with some embodiments;

FIG. 8 is a top view of driving electrodes and sensing electrodes, in accordance with some embodiments;

FIG. 9A is a sectional view of the touch structure in FIG. 8 taken along the AA′ line, in accordance with some embodiments;

FIG. 9B is a sectional view of the touch structure in FIG. 8 taken along the BB′ line, in accordance with some embodiments;

FIG. 10 is a sectional view of a display substrate, in accordance with some embodiments;

FIG. 11 is a top view of sub-pixels, in accordance with some embodiments;

FIG. 12 is a diagram showing orthogonal projections of sub-pixels and a metal mesh on a base, in accordance with some embodiments;

FIG. 13 is a diagram showing orthogonal projections of sub-pixels and a metal mesh on a base, in accordance with some other embodiments;

FIG. 14 is a diagram showing orthogonal projections of sub-pixels and a metal mesh on a base, in accordance with yet some other embodiments;

FIG. 15 is a diagram showing orthogonal projections of sub-pixels and a metal mesh on a base, in accordance with yet some other embodiments;

FIG. 16 is a diagram showing orthogonal projections of sub-pixels and a metal mesh on a base, in accordance with yet some other embodiments;

FIG. 17 is a diagram showing a vertical distance between a contour of a first orthogonal projection and a contour of a second orthogonal projection, in accordance with yet some other embodiments;

FIG. 18 is a sectional view of a display panel, in accordance with some embodiments;

FIG. 19 is a sectional view of a touch display apparatus, in accordance with some embodiments; and

FIG. 20 is a sectional view of another touch display apparatus, in accordance with some embodiments.

### DESCRIPTION OF THE INVENTION

The technical solutions in some embodiments of the present disclosure will be described clearly and completely with reference to the accompanying drawings. However, the described embodiments are merely some but not all of embodiments of the present disclosure. All other embodiments obtained on the basis of the embodiments of the present disclosure by a person of ordinary skill in the art shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, specific features, structures, materials, or characteristics described herein may be included in any one or more embodiments or examples in any suitable manner.

Hereinafter, the terms such as “first” and “second” are used for descriptive purposes only, but are not to be construed as indicating or implying the relative importance or implicitly indicating the number of indicated technical features. Thus, the features defined with “first” and “second” may explicitly or implicitly include one or more of the features. In the description of the embodiments of the present disclosure, the term “multiple”, “a plurality of” or “the plurality of” means two or more unless otherwise specified.

In the description of some embodiments, the expressions “electrically connected” and “connected” and derivatives thereof may be used. For example, the term “electrically connected” may be used in the description of some embodiments to indicate that two or more components are in direct physical or electrical contact with each other. The embodiments disclosed herein are not necessarily limited to the context herein.

The phrase “A and/or B” includes the following three combinations: only A, only B, and a combination of A and B.

The phrase “configured to” used herein means an open and inclusive expression, which does not exclude devices that are applicable to or configured to perform additional tasks or steps.

In addition, the use of the phrase “based on” means openness and inclusiveness, since a process, step, calculation or other action that is “based on” one or more of the stated conditions or values may, in practice, be based on additional conditions or values exceeding those stated.

The term such as “approximately” or “substantially” as used herein includes a stated value and an average value within an acceptable range of deviation of a particular value determined by a person of ordinary skill in the art, considering measurement in question and errors associated with measurement of a particular quantity (i.e., limitations of a measurement system).

Exemplary embodiments are described herein with reference to segmental views and/or plan views as idealized exemplary drawings. In the accompanying drawings, thicknesses of layers and sizes of regions are enlarged for clarity. Thus, variations in shape relative to the accompanying drawings due to, for example, manufacturing technologies and/or tolerances may be envisaged. Therefore, the exemplary embodiments should not be construed as being limited to the shapes of the areas shown herein, but including shape deviations due to, for example, manufacturing. For example, an etched region shown in a rectangular shape generally has a feature of being curved. Therefore, the regions shown in the accompanying drawings are schematic in nature, and their shapes are not intended to show actual shapes of regions in a device, and are not intended to limit the scope of the exemplary embodiments.

With the rapid development of active matrix organic light-emitting diode (AMOLED) display devices, full screen, narrow bezel, high resolution, rollable wearable, foldable, etc. have become important development directions of AMOLED in the future.

The technology of forming touch structures directly on encapsulation layers of organic light-emitting diode (OLED) display panels can produce light and thin touch panels, and this technology can be applied to OLED display apparatuses of being folded and curled.

In consideration of factors such as reducing resistance and improving touch sensitivity, the touch electrodes in the touch structure use metal mesh with advantages of small resistance, small thickness, and fast response speed. In the related art, the touch structures formed directly on the encapsulation layers of the display panels are of two types: flexible metal layer on cell (FMLOC) and flexible single layer on cell (FSLOC), where FSLOC is more convenient for product thinning than FMLOC.

The inventors of the present disclosure have found that under light irradiation, the metal mesh of the touch structure located on the light exit side of the display substrate will develop continuous reflected light in the same direction due to metal reflection, and the human eyes that receive the reflected light can easily perceive the metal mesh, thus reducing the display effect.

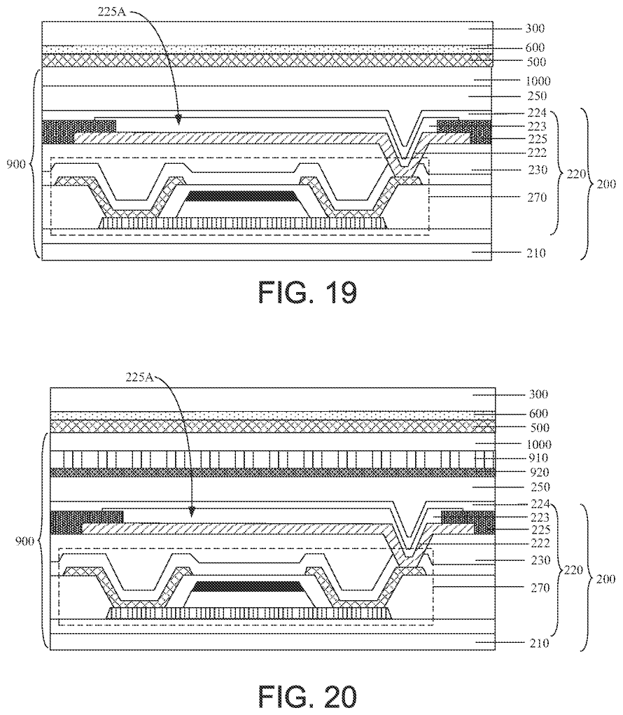

In light of this, as shown in FIG. 18, some embodiments of the present disclosure provide a display panel 900, which is applied to a touch display apparatus, as shown in FIGS. 19 and 20. The touch display apparatus may be an electroluminescent display apparatus or a photoluminescent display apparatus. In the case where the display apparatus is the electroluminescent display apparatus, the electroluminescent display apparatus may be an organic light-emitting diode (OLED) display apparatus, or a quantum dot light-emitting diode (QLED) display apparatus, or a liquid crystal display (LCD), or an electrophoretic display (EPD). In the case where the display apparatus is the photoluminescent display apparatus, the photoluminescent display apparatus may be a quantum dot photoluminescent display apparatus.

The exemplary embodiments of the present disclosure are described by taking the OLED display apparatus as an example, but it should not be construed as being limited to the OLED display apparatus. In some embodiments, as shown in FIGS. 19 and 20, the main structure of the touch display apparatus includes a display panel 900, a touch structure 1000, an anti-reflection structure such as a polarizer 500, a first optically clear adhesive (OCA) layer 600 and a cover plate 300 that are arranged in sequence. In some embodiments, the anti-reflection structure may include color filters and a black matrix.

The display panel 900 includes a display substrate 200 and an encapsulation layer 250 for encapsulating the display substrate 200. The encapsulation layer 250 may be an encapsulation film or an encapsulation substrate.

In some embodiments, as shown in FIG. 19, the touch structure 1000 of the display panel 900 is directly arranged on the encapsulation layer 250. In this way, the display substrate 200 can be regarded as a base substrate of the touch structure 1000, which is conducive to realizing the light and thin of the display apparatus.

In some embodiments, the encapsulation layer 250 includes a first inorganic encapsulation layer, a first organic encapsulation layer and a second inorganic encapsulation layer, or may be a stacked structure of at least one organic layer and at least one inorganic layer. In some embodiments, the anti-reflection structure is formed in the encapsulation layer 250 to play an anti-reflective role and further reduce the thickness of the display apparatus.

In some other embodiments, as shown in FIG. 20, the touch structure 1000 of the display apparatus 900 is arranged on a base substrate 910, and the base substrate 910 is adhered to the encapsulation layer 250 by a second optically clear adhesive layer 920. The material of the base substrate 910 may be, for example, polyethylene terephthalate (PET), polyimide (PI), cyclo olefin polymer (COP), etc.

As shown in FIGS. 18 to 20, each sub-pixel of the display substrate 200 includes a light-emitting device and a driving circuit that are disposed on a base 210, and the driving circuit includes a plurality of thin film transistors 270. The light-emitting device includes an anode 222, a light-emitting layer 223 and a cathode 224, and the anode 222 is electrically connected to a drain of a thin film transistor 270, as a driving transistor, among the plurality of thin film transistors 270 in the driving circuit.

In some embodiments, in a case where the anode 222 is electrically connected to the drain of the thin film transistor 270, as the driving transistor, among the plurality of thin film transistors 270 in the driving circuit, the anode 222 is electrically connected to the drain of the thin film transistor 270 through a transfer electrode, and the transfer electrode is located between a film layer where the drain is located and a film layer where the anode is located.

The display substrate 200 further includes a pixel definition layer 225, the pixel definition layer 225 includes a plurality of light exit openings 225A, and a light-emitting device corresponds to a light exit opening 225A.

In some embodiments, a display functional layer 220 includes the light-emitting layer 223. In some other embodiments, in addition to the light-emitting layer 223, the display functional layer 220 further includes one or more of an electron transport layer (ETL), an electron injection layer (EIL), a hole transport layer (HTL) and a hole injection layer (HIL).

As shown in FIGS. 19 and 20, the display substrate 200 further includes at least one planarization layer 230 disposed between the transistor 270 and the anode 222. In some embodiments, at least one passivation layer is provided on the planarization layer(s) 230.

In the case where the touch display apparatus is an electroluminescent display apparatus, the touch display apparatus may be a top-emission display apparatus; and in this case, the anode 222 close to the base 210 is opaque, and the cathode 224 far away from the base 210 is transparent or translucent. The touch display apparatus may also be a bottom-emission display apparatus; and in this case, the anode 222 close to the base 210 is transparent or translucent, and the cathode 224 far away from the base 210 is opaque. The touch display apparatus may also be a double-sided emission display apparatus; and in this case, the anode 222 close to the base 210 and the cathode 224 far away from the base 210 are both transparent or translucent.

As shown in FIG. 1, some embodiments of the present disclosure provide a touch structure 1000 including a metal mesh 100, and the metal mesh 100 includes a plurality of metal conductive lines 110.

The metal mesh 100 has a plurality of openings 100A, each opening 100A is enclosed by a plurality of metal conductive lines 110, and a shape of each opening 100A is asymmetric.

A touch region of the touch structure 1000 may overlap with a display region AA (also known as an active area) of the display substrate 200.

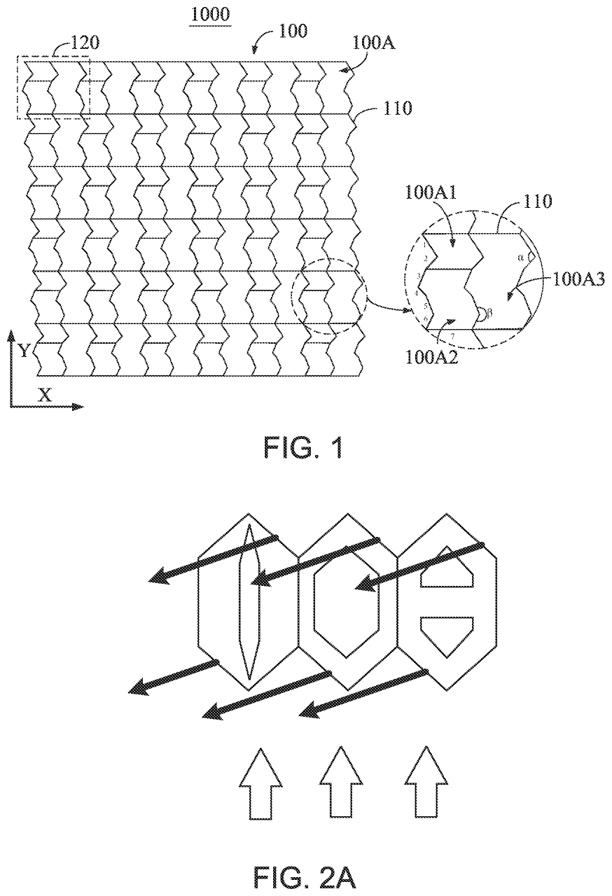

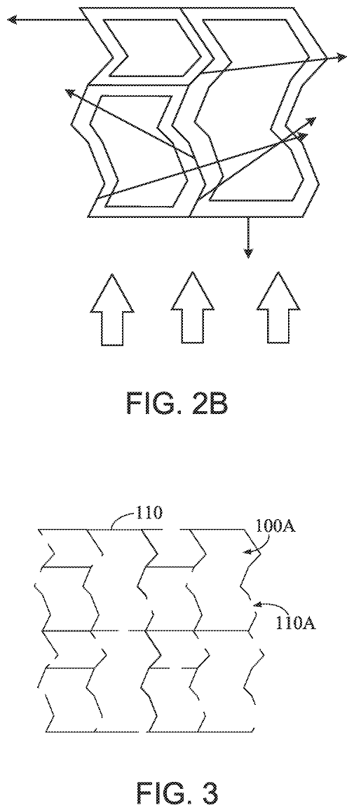

As shown in FIGS. 2A and 2B, the hollow arrows at the bottom of the figures represent incident light, and the black arrows represent reflected light. As shown in FIG. 2A, when the opening is symmetrical in shape, incident light in a direction is reflected by the opening, resulting in fewer directions of the reflected light. Light in each reflection direction is concentrated, so it is easy to form continuous reflected light in the same direction, causing the human eyes to perceive the metal mesh.

As shown in FIG. 2B, when the opening is asymmetrical in shape, incident light in a direction is reflected by the opening, resulting in more directions of the reflected light. Light in each reflection direction is scattered, resulting in a scattering-like effect. The human eye cannot perceive the reflected light, thus eliminating or reducing the visibility of the metal mesh to the human eyes.

Therefore, by setting the shape of the opening 100A to be asymmetrical, it can increase the extension directions of the metal conductive lines 110 in the metal mesh 100, and in turn increase the direction of the reflected light of the entire metal mesh 100, realizing or approaching the effect of light scattering, and eliminating or reducing the phenomenon of continuous reflected light in the same direction of the metal mesh 100. As a result, the visibility of the metal mesh to human eyes is eliminated or reduced, and the display effect is improved.

In addition, when the external light irradiates the display panel, the metal mesh 100 of the touch structure 1000 proximate to a top layer reflects the external light, which is the main reason to cause the Mura phenomenon (the phenomenon of display of uneven brightness and display of various traces). In the embodiments of the present disclosure, by the design of the asymmetric-shaped openings 100A, it can realize the scattering effect of reflected light, and in turn eliminate or reduce the Mura phenomenon of the display panel 900 and improve the display effect of the display panel 900.

In some embodiments, at least one metal conductive line 110 among a plurality of metal conductive lines 110 included in a single opening 100A includes at least one disconnected hole 110A, as shown in FIG. 3. Shapes of ends of different disconnected holes 110A may be the same or different. For example, the shapes of ends of two disconnected holes 110A of the same metal conductive line 110 are different; or, the shapes of the ends of the disconnected hole(s) 110A of the same metal conductive line 110 are the same, and the shapes of the ends of the disconnected holes 110A of different metal conductive lines 110 are different; or, the shapes of the ends of the disconnected holes 110A of the plurality of metal conductive lines 110 are all the same; or, the shapes of the ends of the disconnected holes 110A of the plurality of metal conductive lines 110 are all different.

Widths of a plurality of metal conductive lines 110 included in a single opening 100A may be the same or different. For example, the widths of the plurality of metal conductive lines 110 included in the single opening 100A are all the same; or the widths of the plurality of metal conductive lines 110 included in the single opening 100A are all different; or, among the plurality of metal conductive lines 110 included in the single opening 100A, widths of a part of metal conductive lines 110 are the same, widths of another part of metal conductive lines 110 are the same, and the widths of the two parts of metal conductive lines 110 are different.

It should be noted that, in the case where the two metal conductive lines 110 have disconnected holes 110A whose ends are in the same shape, since the widths of the two metal conductive lines 110 are different, the sizes of the ends of the disconnected holes 110A are also different.

Due to the design of the disconnected hole 110A, compared with FIG. 2B, in FIG. 3, it is possible to reduce metal that reflects light in the opening 100A, and in turn reduce the reflected light of the metal mesh 100 and eliminate or reduce the visibility of the metal mesh to the human eyes.

In some embodiments, the opening 100A is enclosed by N metal connective lines 110 that are connected end to end, and the N metal conductive lines 110 have M different extension directions; N and M are integers, N is greater than or equal to 5 (N≥5), and M is greater than or equal to 3 and less than or equal to N (3≤M≤N).

The two metal conductive lines 110 have the same extension direction, which means that the two metal conductive lines 110 are parallel to each other. The two metal conductive lines 110 have different extension directions, which means that the two metal conductive lines 110 intersect or the extension lines of the two metal conductive lines 110 intersect. For example, the number N of metal conductive lines enclosing the opening 100A may be 5, 7, 9, 10, or 15. For example, when the number of metal conductive lines enclosing the opening 100A is 5, the extension directions of the 5 metal conductive lines may be 3, 4 or 5. In the case where M is equal to N (M=N), the N metal conductive lines enclosing the opening all extend in different directions. In the case where M is less than N (M<N), at least two metal conductive lines extend in the same direction.

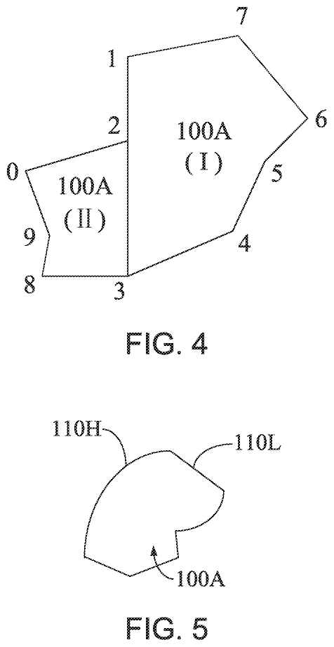

As shown in FIG. 4, the point 1, point 2 and point 3 are located on the same straight line and are three position points on a metal conductive line. In some implementations of the present disclosure, it is considered that the metal conductive line includes: a straight metal conductive line with the point 1 and point 2 as endpoints, and another straight metal conductive line with the point 2 and point 3 as endpoints.

For example, the opening 100A(I) is enclosed by the line segment 12, line segment 23, line segment 34, line segment 45, line segment 56, line segment 67 and line segment 71 that are connected end to end, and the opening 100A(II) is enclosed by the line segment 23, line segment 38, line segment 89, line segment 90 and line segment 02 that are connected end to end. It should be noted that the above line segments each represent a single metal conductive line in the metal mesh 100.

In the case where the number of metal conductive lines 110 enclosing the opening 100A is greater than or equal to 8, and types of angles between all edges of the opening 110A and a horizontal direction are greater than or equal to 4, the opening 100A can achieve good light scattering effect.

For example, in the three openings 100A shown in FIG. 1, the first type of opening 100A1 is enclosed by 6 edges, the second type of opening 100A2 is enclosed by 10 edges, and the third type of opening 100A3 is enclosed by 14 edges. There are seven different angles between the metal conductive lines 110 of the three openings 100A and the horizontal direction, so that the light scattering effect can be well achieved.

The more the number of N and M, the more the direction of the reflected light of the metal mesh, and the closer it is to the light scattering effect. The phenomenon of continuous reflected light in the same direction of the metal mesh is eliminated or reduced, and it is easier to eliminate or reduce the visibility of the metal mesh to the human eyes and improve the display effect.

In some embodiments, any two metal conductive lines 110 among the at least N metal conductive lines 110 are asymmetrical to each other.

The description that the two metal conductive lines 110 are asymmetrical to each other means that: the two metal conductive lines 110 have symmetrical extension directions and different extension lengths; or, the two metal conductive lines have asymmetrical extension directions and the same extension length; or, the two metal conductive lines have asymmetrical extension directions and different extension lengths.

Any two metal conductive lines 110 among the N metal conductive lines 110 that collectively enclose the opening 100A are asymmetric to each other. Compared with the case where a plurality of metal conductive lines 110 enclosing the opening 100A that include two symmetrical metal conductive lines 110, it is possible to increase the reflection direction of the incident light by the metal conductive lines 110 and reduce the amount of reflected light in each reflection direction, causing the light to be further scattered. Therefore, the direction of the reflected light of the entire metal mesh 100 can be further increased, which is conducive to eliminating or reducing the visibility of the metal mesh 100 to human eyes and improving the display effect.

In some embodiments, the metal mesh 100 includes at least one type of opening 100A. Each type of opening 100A includes a plurality of openings 100A with the same shape, and different types of openings 100A have different shapes.

The metal mesh 100 includes one or more types of openings 100A. For example, as shown in the enlarged view in FIG. 1, the metal mesh 100 includes three types of openings 100A, the shape of the first type of opening 100A1 is an asymmetric shape enclosed by 6 edges, the shape of the second type of opening 100A2 is an asymmetric shape enclosed by 10 edges, and the shape of the third type of opening 100A3 is an asymmetric shape enclosed by 14 edges. Different types of openings 100A may have the same number of edges but different shapes. The above is only described by taking different numbers of edges as an example.

Considering the lengths and angles of the seven metal conductive lines 110 in the enlarged view in FIG. 1 as an example, the metal conductive line 1 has the length of 30 μm and the angle of 60° with the X direction, the metal conductive line 2 has the length of 24 μm and the angle of 128° with the X direction, the metal conductive line 3 has the length of 24 μm and the angle of 11° ° with the X direction, the metal conductive line 4 has the length of 14 μm and the angle of 5° ° with the X direction, the metal conductive line 5 has the length of 20 μm and the angle of 70° with the X direction, the metal conductive line 6 has the length of 28 μm and the angle of 103° with the X direction, and the metal conductive line 7 has the length of 60 μm and the angle of 0° with the X direction.

The shapes of a plurality of openings 100A among the same type of openings 100A are the same, and the shapes of different types of openings 100A are different from each other. In addition, the number of openings of different types of openings 100A may be the same or different, which is not limited here.

In some embodiments, as shown in FIG. 1, the metal mesh 100 includes a plurality of opening units 120, and each opening unit 120 includes one or more openings 100A; and at least one opening in the opening unit 120 is enclosed by more than 8 metal conductive lines 110 that are connected end to end.

The plurality of opening units 120 of the metal mesh 100 may be a plurality of identical opening units 120, or may be a plurality of different opening units 120, which is not limited here.

The plurality of opening units 120 may be repeated in the display region, and there is no other opening 100A between two adjacent opening units 120; the plurality of opening units 120 may also be scattered in the display region, and there is other opening 100A between adjacent opening units 120, which will not be limited here.

The number of openings 100A in a single opening unit 120 may be 1, 3, 5, etc. In the case where a single opening unit 120 includes a plurality of openings 100A, the shapes of the plurality of openings 100A may be the same or different; or, a part of openings 100A have the same shape, and another part of openings 100A have different shapes.

The greater the number of metal conductive lines 110 enclosing the opening 100A, the greater the increase in the direction of reflected light. More than 8 metal conductive lines 110 can achieve good light scattering effect. At least one opening in each opening unit 120 is enclosed by more than 8 metal conductive lines 110 that are connected end to end, which can ensure the diversity of reflected light directions of the opening unit 120, reduce the amount of reflected light in each reflected light direction, and achieve a scattering-like effect. Therefore, the human eyes cannot perceive the reflected light, which is conducive to eliminating or reducing the visibility of the metal mesh 100 to the human eyes and improving the display effect.

In some embodiments, the opening unit 120 includes at least three openings 100A; the at least three openings 100A in the opening unit 120 have shapes different from each other and/or areas different from each other.

The number of openings 100A in the opening unit 120 may be 3, 4, 5, etc. The at least three openings 100A in the opening unit 120 may have different shapes and the same area, or may have the same shape and different areas, or may have different shapes and different areas. When the shapes are different from each other and the areas are different from each other, in the same opening unit 120, there will not be two openings 100A with the same shape, and there will not be two openings 100A with the same area.

In the display substrate, a single pixel unit includes at least three sub-pixels. For example, the pixel unit includes one blue sub-pixel, one red sub-pixel and one green sub-pixel; or, the pixel unit includes one blue sub-pixel, one red sub-pixel and two green sub-pixels; or, the pixel unit includes one blue sub-pixel, one red sub-pixel, one green sub-pixel and one white sub-pixel.

This is similar to a single opening unit 120 including at least three openings 100A. Therefore, the opening unit 120 in the metal mesh 100 can correspond to the pixel unit in the display substrate. For example, the number of openings 100A in the opening unit 120 is same as the number of sub-pixels in the pixel unit. In this way, the arrangement position of the openings 100A in the opening unit 120 may also be determined with reference to the arrangement position of the sub-pixels. A mapping relationship in which an opening 100A of one shape corresponds to a sub-pixel may be used, and the arrangement position of the openings in the opening unit is determined by using the arrangement position of the sub-pixels in the pixel unit.

In some embodiments, as shown in FIG. 5, the shape of the metal conductive line 110 may include a straight segment, that is, the metal conductive line 110 includes a straight metal conductive line 110L; the shape of the metal conductive line 110 may also include a curved segment, that is, the metal conductive line 110 includes a curved metal conductive line 110H.

The N metal conductive lines 110 enclosing the opening 100A may all be straight metal conductive lines 110L or may all be curved metal conductive lines 110H, or part of them may be straight metal conductive lines 110L and the remaining part of them may be curved metal conductive lines 110H. In the case where the metal conductive lines 110 enclosing the opening 100A are all straight metal conductive lines 110L, the metal mesh 100 is an asymmetric polygon metal mesh (APM).

As shown in FIG. 1, the shape of the opening 100A may include at least one outwardly protruding convex angle α. The convex angle α may be an angle formed by connecting two straight metal conductive lines 110L, or may be an angle formed by connecting two curved metal conductive lines 110H, or may be an angle formed by connecting a straight metal conductive line 110L and a curved metal conductive line 110H. A convex angle α close to a side of the center of the opening 100A is greater than 0° and less than 180°, such as 30°, 60°, 90°, 120° or 150°.

In addition, the shape of the opening 100A may include at least one inwardly protruding concave angle β. The concave angle β may be an angle formed by connecting two straight metal conductive lines 110L, or may be an angle formed by connecting two curved metal conductive lines 110H, or may be an angle formed by connecting a straight metal conductive line 110L and a curved metal conductive line 110H. A concave angle β close to the side of the center of the opening 100A is greater than 180° and less than 360°, such as 210°, 240°, 270°, 300° or 330°.

In some embodiments, the material of the metal conductive line 110 includes at least one of copper (Cu), silver (Ag), nanocarbon or graphene. Considering an example in which the material of the metal conductive line 110 includes silver, silver refers to simple silver, nano-silver, or other structural forms of silver; in addition, the metal conductive line 110 may also be made of a compound including silver element, which will not be limited here.

Considering an example in which the material of the metal conductive line 110 includes copper and nanocarbon, copper refers to simple copper, nanocopper, or other structural forms of copper; nanocarbon refers to carbon nanotubes, carbon nanofibers, or other structural forms such as nanocarbon spheres. The material of the metal conductive line 110 may include a mixture of any of the above-mentioned copper forms and any of the above-mentioned nanocarbon forms.

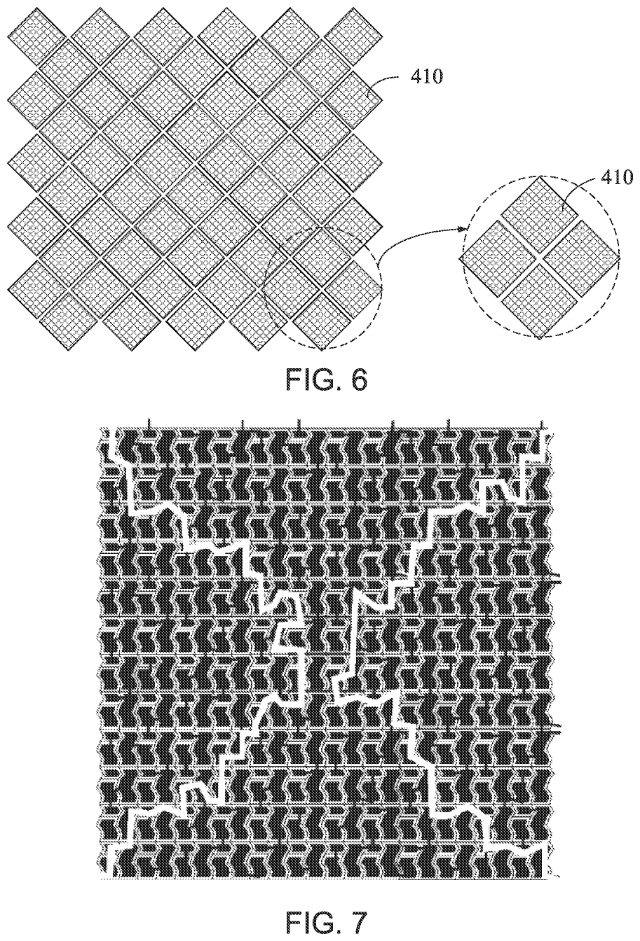

In some embodiments, as shown in FIG. 6, the touch structure includes a plurality of touch electrodes 410, each touch electrode 410 includes a metal mesh, and the plurality of touch electrodes are configured to be independently connected to a touch chip.

The plurality of touch electrodes 410 are insulated from each other, and the plurality of touch electrodes 410 are arranged in the display region. The plurality of touch electrodes 410 may be in the same shape, and the touch electrode 410 may be in a shape of a rhombus or substantially in a shape of a rhombus, where “substantially in a shape of a rhombus” means that the touch electrode 410 is in a shape of a rhombus as a whole, but is not limited to a shape of a standard rhombus. For example, the boundary of the touch electrode 410 is allowed to be non-linear (such as a zigzag) as shown in FIG. 7. FIG. 7 is an enlarged view of border regions of two touch electrodes 410 arranged horizontally. The thicker and irregular white lines on the left and right sides in FIG. 7 are the boundaries of the two touch electrodes 410. The two white lines are spaced apart, which means that the two adjacent touch electrodes 410 are spaced apart from each other. The black filling structures in FIG. 7 are sub-pixels.

In addition, the shape of the touch electrode 410 is not limited to a rhombus or a rough rhombus, but may also be a rectangle, a strip, etc.

The touch electrode 410 includes a metal mesh, which means that each touch electrode adopts a metal mesh structure. Compared with a case of using indium tin oxide (ITO) to form a planar electrode as the touch electrode 410, the touch electrode 410 of a metal mesh structure has small resistance and high sensitivity, which can improve the touch sensitivity of the touch display panel. In addition, the touch electrode 410 using a metal mesh structure has high mechanical strength, which can reduce the weight of the touch display panel. When the touch display panel is used in a display apparatus, a light and thin design of the display apparatus can be realized.

A plurality of touch electrodes 410 including metal mesh structures may be arranged in the same metal layer, that is, a FSLOC structure, which facilitates the light and thin design of the display apparatus.

Each touch electrode 410 is independently electrically connected to the touch chip, and the touch chip provides a voltage to the touch electrode 410, so that the touch electrode 410 can independently develop a capacitance with ground. Subsequently, a touch point in the display region is determined by sensing changes in a plurality of capacitances.

The metal conductive lines of the metal mesh in the touch electrode 410 may be arranged directly opposite to gaps between light-emitting regions 221A of multiple sub-pixels 221 in the display region, thus preventing the metal mesh from blocking the light emission of and ensuring the luminous efficiency of the display apparatus.

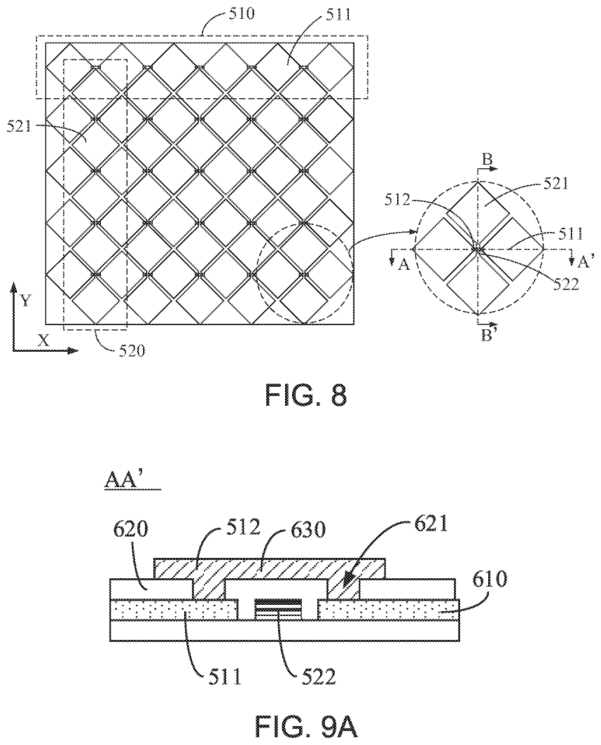

In some embodiments, as shown in FIG. 8, the touch structure includes a plurality of driving units 510 and a plurality of sensing units 520 that are insulated from each other; each driving unit 510 includes a plurality of driving electrodes 511 arranged side by side along the first direction X, and a first connection portion 512 that electrically connects two adjacent driving electrodes 511; each sensing unit 520 includes a plurality of sensing electrodes 521 arranged side by side along the second direction Y, and a second connection portion 522 that electrically connects two adjacent sensing electrodes 521. The first direction X and the second direction Y intersect.

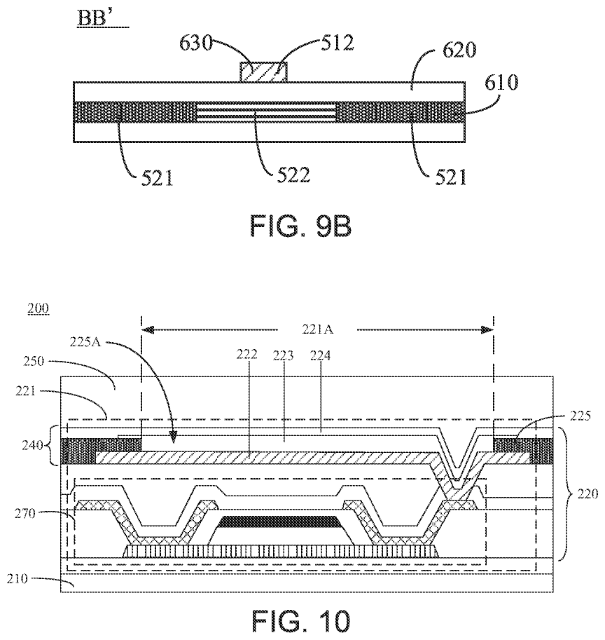

As shown in FIGS. 9A and 9B, the touch structure includes a first metal layer 610, an insulating layer 620 and a second metal layer 630 that are stacked in sequence, and the insulating layer 620 is provided therein with a plurality of via holes 621.

For example, the driving electrodes 511, the first connection portion 512 and the sensing electrodes 521 are located in one of the first metal layer 610 and the second metal layer 630, the second connection portion 522 is located in another one of the first metal layer 610 and the second metal layer 630, and the second connection portion 522 is electrically connected to the two adjacent sensing electrodes 521 through via holes 621.

For example, the driving electrodes 511, the second connection portion 522 and the sensing electrodes 521 are located in one of the first metal layer 610 and the second metal layer 630, the first connection portion 512 is located in another one of the first metal layer 610 and the second metal layer 630, and the first connection portion 512 is electrically connected to the two adjacent driving electrodes 511 through via holes 621.

For example, the driving electrodes 511, the sensing electrodes 521, the first connection portion 512 and the second connection portion 522 each include a metal mesh. The opening shape and related arrangement of the metal mesh adopt the design described in the above embodiments. In this way, it may be possible to increase the directions of the reflected light of the touch structure 1000, reduce the amount of reflected light in each direction of the reflected light, and realize a scattering-like effect. As a result, the human eyes cannot perceive the reflected light, which eliminate or reduce the visibility of the metal mesh to the human eyes and improves the display effect.

As shown in FIG. 8, the first direction X and the second direction Y intersect, for example, the first direction X and the second direction Y are perpendicular to each other. For example, the first direction X may be the horizontal direction of the touch display apparatus, and the second direction Y may be the longitudinal direction of the touch display apparatus; or the first direction X is a row direction of the pixel arrangement of the touch display apparatus, and the second direction Y is a column direction of the pixel arrangement of the touch display apparatus.

It should be noted that multiple drawings of the present disclosure only illustrate examples in which the first direction X is the horizontal direction and the second direction Y is the longitudinal direction. In the present disclosure, the technical solutions obtained by rotating the drawings by 90 degrees are also within the protection scope of the present disclosure.

The first connection portion 512 and the second connection portion 522 are located in different metal layers of the touch structure at least at the intersection position. That is, at the intersection position, one of the first connection portion 512 and the second connection portion 522 is located in the first metal layer 610, the other is located in the second metal layer 630, and the first connection portion 512 and the second connection portion 522 are separated by the insulating layer 620 at the intersection position, thus avoiding the crosstalk of touch signals transmitted by the first connection portion 512 and the second connection portion 522.

For example, the first connection portion 512 is located in the first metal layer 610, and two driving electrodes 511 located in the first metal layer 610 and adjacent along the first direction X are connected to each other directly through the first connection portion 512. The second connection portion 522 is located in the second metal layer 630, and two sensing electrodes 521 located in the first metal layer 610 and adjacent along the second direction Y are connected to the second connection portion 522 through different via holes 621 in the insulating layer 620, thereby realizing the connection between the two sensing electrodes 521.

For example, as shown in FIGS. 8, 9A and 9B, the first connection portion 512 is located in the second metal layer 630, and two driving electrodes 511 located in the first metal layer 610 and adjacent along the first direction X are connected to the first connection portion 512 through different via holes 621 in the insulating layer 620, thereby realizing the connection between the two driving electrodes 511. The second connection portion 522 is located in the first metal layer 610, and two sensing electrodes 521 located in the first metal layer 610 and adjacent along the second direction Y are connected to each other directly through the second connection portion 522.

The second connection portion 522 is located in the first metal layer 610, and two sensing electrodes 521 located in the first metal layer 610 and adjacent along the second direction Y are connected to each other directly through the second connection portion 522. The first connection portion 512 is located in the second metal layer 630, two driving electrodes 511 located in the first metal layer 610 and adjacent along the first direction X are connected to the first connection portion 512 through different via holes 621 in the insulating layer 620, thereby realizing the connection between the two driving electrodes 511.

It should be noted that FIGS. 9A and 9B only illustrate examples in which the driving electrode 511, the second connection portion 522 and the sensing electrode 521 are located in the first metal layer 610, and the first connection portion 512 is located in the second metal layer 630. Electrical connection manners and structural diagrams in other situations may be derived without any doubt using the same manners and principles. In addition, the driving electrode 511 and the sensing electrode 521 are filled with different patterns in order to distinguish different electrodes. The driving electrode 511 and the sensing electrode 521 may be formed using the same material and the same processes.

In some embodiments, an area of the driving electrode 511 and/or the sensing electrode 521 may be in a range from 9 mm² to 25 mm², that is, the area of at least one of the driving electrode 511 and the sensing electrode 521 may be in a range from 9 mm² to 25 mm². The area of the driving electrode 511 may be in a range from 9 mm² to 25 mm², or the area of the sensing electrode 521 may be in a range from 9 mm² to 25 mm², or the areas of the driving electrode 511 and the sensing electrode 521 may each be in a range from 9 mm² to 25 mm². The range from 9 mm² to 25 mm² may include 10 mm², 12 mm², 14 mm², 16 mm², 20 mm² or 23 mm². When the shape of the driving electrode 511 is a rhombus, lengths of two edges of the driving electrode 511 may be in a range from 3 mm to 5 mm, such as 3.2 mm, 3.8 mm, 4 mm, 4.3 mm or 4.7 mm. For example, the length of one edge of the rhombic driving electrode is 3.8 mm, and the length of another edge of the rhombic driving electrode is 4.7 mm; alternatively, the length of one edge of the rhombic driving electrode is 4 mm, and the length of another edge of the rhombic driving electrode is 4.5 mm.

In a display apparatus with a pixel density greater than 500 pixels per inch (PPI), the design of the openings of the metal mesh may be used to form touch electrodes with an edge length less than 0.3 mm that are arranged in an array and cannot be perceived by the human eyes, thereby eliminating the visible display defect of the driving electrodes composed of edges in a range from 3 mm to 5 mm to the human eyes. In medium and large size display apparatuses with pixel densities less than 400 PPI, due to the large light-emitting regions of the sub-pixels, the openings of the metal mesh 100 are limited by resistive and capacitive loads. The edge length of the minimum touch electrode formed through the design of the opening 100A is generally larger than 0.3 mm, resulting in the visible display defect easily viewed by the human eyes. In the exemplary embodiments of the present disclosure, the touch structure 1000 adopts the design of the asymmetric-shaped opening enclosed by a plurality of metal edges, and when irradiated by strong light, the metal mesh develops multi-directional reflections to realize a scattering-like effect, thereby eliminating the visibility of the metal mesh 100 to the human eyes.

In some embodiments, the width of the metal conductive line 110 is in a range from 1 μm to 20 μm, such as 2 μm, 3.5 μm, 4.7 μm, 8 μm, 15 μm or 18 μm. The width of the metal conductive line 110 refers to the width in a direction perpendicular to the extension direction of the metal conductive line 110. For example, when the metal conductive line 110 is a straight metal conductive line 110L, the width of the metal conductive line 110 is a width of its cross section; when the metal conductive line 110 is a curved metal conductive line 110H, the width of the metal conductive line 110 is a width of a section, and the section is perpendicular to the tangential direction of the sectioning position.

As shown in FIG. 10, some embodiments of the present disclosure provide a display substrate 200 including a base 210 and a display functional layer 220 disposed on the base 210. The display functional layer 220 includes a plurality of sub-pixels 221, and a shape of a light-emitting region of each sub-pixel is asymmetric.

The base 210 may be an organic base or an inorganic base. The base 210 may be made of, for example, polyethylene terephthalate (PET), polyimide (PI), cyclo olefin polymer (COP), etc.

The display functional layer 220 may include a plurality of functional film layers for forming the sub-pixel 221, such as film layers for forming the thin film transistors 270, the anode 222, the light-emitting layer 223, the cathode 224, etc. The light-emitting region 221A of the sub-pixel 221 can be understood as an effective light-emitting surface of the sub-pixel 221, and the shape of the light-emitting region 221A of each sub-pixel 221 is asymmetric.

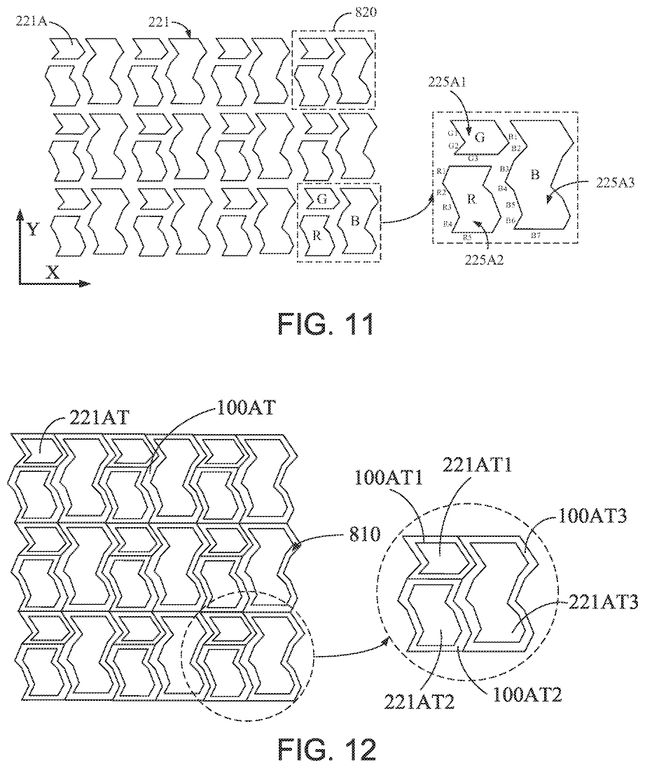

The light-emitting regions 221A of the plurality of sub-pixels 221 may have the same asymmetric shape; or, as shown in FIG. 11, the light-emitting regions 221A of sub-pixels 221 of the same color may have the same shape, and the light-emitting regions 221A of sub-pixels 221 of different colors may have different shapes; or, the light-emitting regions 221A of sub-pixels 221 of the same color may have various different shapes, and the light-emitting regions 221A of sub-pixels 221 of different colors may have different shapes; or, the light-emitting regions 221A of sub-pixels 221 of different colors may have the same shape.

The following is described by taking the lengths and angles of 3 contour edges of the green sub-pixel G, 5 contour edges of the red sub-pixel R, and 7 contour edges of the blue sub-pixel B in the enlarged view of FIG. 11 as an example.

The contour edge G1 has the length of 20 μm and the angle of 60° with the X direction. The contour edge G2 has the length of 16 μm and the angle of 128° with the X direction. The contour edge G3 has the length of 36 μm and the angle of 0° with the X direction.

The contour edge R1 has the length of 16 μm and the angle of 110° with the X direction. The contour edge R2 has the length of 12 μm and the angle of 50° with the X direction. The contour edge R3 has the length of 18 μm and the angle of 70° with the X direction. The contour edge R4 has the length of 20 μm and the angle of 103° with the X direction. The contour edge R5 has the length of 36 μm and the angle of 0° with the X direction.

The contour edge B1 has the length of 22 μm and the angle of 60° with the X direction. The contour edge B2 has the length of 24 μm and the angle of 128° with the X direction. The contour edge B3 has the length of 24 μm and the angle of 110° with the X direction. The contour edge B4 has the length of 14 μm and the angle of 50° with the X direction. The contour edge B5 has the length of 18 μm and the angle of 70° with the X direction. The contour edge B6 has the length of 20 μm and the angle of 103° with the X direction. The contour edge B7 has the length of 36 μm and the angle of 0° with the X direction.

For example, the light-emitting regions of the blue sub-pixels have one shape, the light-emitting regions of the red sub-pixels have multiple shapes, the light-emitting regions of the green sub-pixels have one shape, and the shapes of the light-emitting regions of sub-pixels of all colors are different from each other.

For example, the light-emitting regions of the blue sub-pixels have two shapes, the light-emitting regions of the red sub-pixels have two shapes, and the light-emitting regions of the green sub-pixels have one shape; and one shape of the light-emitting regions of the red sub-pixels and one shape of the light-emitting regions of the blue sub-pixels are the same, but the remaining shapes are different.

The asymmetric shape of the sub-pixel 221 may be different from, or at least partially the same as, the asymmetric shape of the opening 100A in the metal mesh 100, which is not limited here.

It should be noted that the shapes of the contour edges of the light-emitting region 221A of the sub-pixel 221 may include a straight line segment or a curved line segment. As for the details of the shape, reference may be made to the shape of the opening 100A in FIG. 5.

The contour edges that constitute the contour of the light-emitting region 221A of a single sub-pixel 221 may all be straight line contour edges, or may all be curved line contour edges, or part of them may be straight line contour edges and the remaining part of them may be curved line contour edges. When the contour edges that enclose the light-emitting region 221A of the sub-pixel 221 are all straight line contour edges, the light-emitting region 221A of the sub-pixel 221 is an asymmetric polygon pixel (APP).

In some embodiments, the contour of the light-emitting region 221A is composed of N edges that are connected end to end, and the N edges have M different extension directions; N and M are integers, N≥5, and 3≤M≤N.

Two edges having the same extension direction means that the two edges are parallel to each other, and two edges having different extension directions means that the two edges intersect or the extension lines of the two edges intersect. For example, the number N of edges enclosing the light-emitting region 221A may be 5, 7, 9, 10 or 15. For example, when the number of edges enclosing the light-emitting region 221A is 5, the extension directions of the 5 edges may be 3, 4 or 5. In the case where M=N, the N edges enclosing the light-emitting region all extend in different directions; in the case where M<N, at least two edges extend in the same direction.

In some embodiments, any two edges among the N edges are asymmetrical to each other. Two edges asymmetrical to each other may mean that: the two edges extend in symmetrical directions and have different extension lengths; or the two edges extend in asymmetrical directions and have the same extension lengths; or the two edges extend in asymmetrical directions and have different extension lengths.

In some embodiments, the display functional layer 220 includes sub-pixels 221 of a plurality of colors, and a contour of a light-emitting region 221A of a sub-pixel 221 of at least one color is composed of more than 8 edges connected end to end.

That is, contours of light-emitting regions 221A of sub-pixels 221 of one color are each composed of more than 8 edges connected end to end. The contours of the light-emitting regions 221A of the sub-pixels 221 of the one color may have the same shape; or, the contours of the light-emitting regions 221A of the sub-pixels 221 of the one color may have multiple shapes, and each shape has more than 8 edges. In a first situation, the numbers of edges of the contours of the light-emitting regions 221A of the sub-pixels 221 of the one color are the same. In a second situation, the numbers of edges of the contours of the light-emitting regions 221A of the sub-pixels 221 of the one color may be different.

For example, the contours of the light-emitting regions 221A of the blue sub-pixels 221 each have a 9-sided asymmetric shape. In this case, the light-emitting regions 221A of the blue sub-pixels 221 each have 9 contour edges.

For example, the contours of the light-emitting regions 221A of the blue sub-pixels 221 have an 8-sided asymmetric shape and a 10-sided asymmetric shape. In this case, light-emitting regions 221A of a part of the blue sub-pixels 221 have 8 contour edges, and light-emitting regions 221A of another part of the blue sub-pixels 221 have 10 contour edges.

For example, the contours of the light-emitting regions 221A of the blue sub-pixels 221 have three different 8-sided asymmetric shapes. In this case, the light-emitting regions 221A of the blue sub-pixels 221 each have 8 contour edges.

In addition, the contours of the light-emitting regions 221A of the sub-pixels 221 of multiple colors may each be composed of more than 8 edges connected end to end. For example, the contours of the light-emitting regions 221A of the sub-pixels 221 of two colors are each composed of more than 8 edges connected end to end; or, the contours of the light-emitting regions 221A of the sub-pixels 221 of all colors are each composed of more than 8 edges connected end to end. As for the sub-pixels 221 of each color, reference may be made to the above-mentioned situation in which the contours of the light-emitting regions 221A of the sub-pixels 221 of one color are each composed of more than 8 edges connected end to end, and details will not be repeated here.

In some embodiments, the light-emitting regions 221A of sub-pixels 221 of different colors have different shapes and/or different areas.

The light-emitting regions 221A of the sub-pixels 221 of different colors have different shapes, which means that shape(s) of the light-emitting regions 221A of the sub-pixels 221 of one color are different from shapes of the light-emitting regions 221A of the sub-pixels 221 of other colors. The light-emitting regions 221A of the sub-pixels 221 of one color may have one or more shapes. In the case where the light-emitting regions 221A of the sub-pixels 221 of one color have multiple shapes, the light-emitting regions 221A of the sub-pixels 221 of other colors do not have the same shape as any one of the multiple shapes.

For example, the light-emitting regions 221A of the sub-pixels 221 of one color have shape 1 and shape 2, and any shape of the light-emitting regions 221A of the sub-pixels 221 of other colors is different from the shape 1 and shape 2.

The light-emitting regions 221A of the sub-pixels 221 of different colors have different areas, which mean that area(s) of the light-emitting regions of the sub-pixels 221 of one color are different from areas of the light-emitting regions 221A of the sub-pixels 221 of other colors. The light-emitting regions 221A of the sub-pixels 221 of one color may have one or more areas. In the case where the light-emitting regions 221A of the sub-pixels 221 of one color have multiple areas, the light-emitting regions 221A of the sub-pixels 221 of other colors do not have the same area as any one of the multiple areas.

For example, the light-emitting regions 221A of the sub-pixels 221 of one color have area 1 and area 2, and any area of the light-emitting regions 221A of the sub-pixels 221 of other colors is different from the area 1 and area 2.

The light-emitting regions 221A of sub-pixels 221 of different colors may have different shapes and different areas, or may have the same shape but different areas, or may have different shapes but the same area.

For example, the shape(s) of the light-emitting regions of the blue sub-pixels and the shape(s) of the light-emitting regions of the red sub-pixels are the same, but the area(s) of the light-emitting regions of the blue sub-pixels and the area(s) of the light-emitting regions of the red sub-pixels are different.

For example, the shape(s) of the light-emitting regions of the blue sub-pixels and the shape(s) of the light-emitting regions of the white sub-pixels are different, but the area(s) of the light-emitting regions of the blue sub-pixels and the area(s) of the light-emitting regions of the white sub-pixels are the same.

In some embodiments, as shown in FIG. 10, the display functional layer includes a pixel definition layer 225 which is provided therein with a plurality of light exit openings 225A, each light exit opening 225A determines a light-emitting region 221A of a sub-pixel, and a shape of the light exit opening 225A is substantially the same as a shape of the light-emitting region 221A of the sub-pixel 221.

The structure of the pixel defining layer 225 is similar to a grid, and blocking walls form a plurality of light exit openings 225A. A sub-pixel region is provided therein with a light exit opening 225A. The light exit opening 225A is configured to determine a light-emitting region 221A of a sub-pixel 221. Light emitted by the light-emitting layer 223 passes through the light exit opening 225A, so that the light-emitting region 221A is obtained. Therefore, the shape of the light exit opening 225A is substantially the same as the shape of the light-emitting region 221A of the sub-pixel 221.

In the pixel definition layer 225, a plurality of light exit openings 225A configured as the light-emitting regions 221A of the sub-pixels 221 of the same color may have the same shape, and light exit opening 225A configured as the light-emitting regions 221A of the sub-pixels 221 of different colors may have different shapes.

In some embodiments, as shown in FIG. 11, the display functional layer 220 includes blue sub-pixels B, red sub-pixels R and green sub-pixels G. The area of the light-emitting region 221A of the blue sub-pixel B is greater than the area of the blue sub-pixel B. The area of the light-emitting region 221A of the red sub-pixel R is greater than the area of the light-emitting region 221A of the green sub-pixel G.

The pixel definition layer 225 includes first light exit openings 225A1, second light exit openings 225A2 and third light exit openings 225A3. The first light exit openings 225A3 are configured to determine the light-emitting regions 221A of the blue sub-pixels B, the second light exit openings 225A2 are configured to determine the light-emitting regions 221A of the red sub-pixels R, and the third light exit openings 225A1 are configured to determine the light-emitting regions 221A of the green sub-pixels G.

The opening area of the first light exit opening 225A3 is greater than the opening area of the second light exit opening 225A2, and the opening area of the second light exit opening 225A2 is greater than the opening area of the third light exit opening 225A1.

It should be noted that the display functional layer 220 includes the blue sub-pixels B, the red sub-pixels R and the green sub-pixels G, but is not limited to the sub-pixels of the above three colors, and may further include sub-pixels of other color(s) such as white sub-pixels. The above is merely described by taking the blue sub-pixels, red sub-pixels and green sub-pixels as an example.

The first light exit opening 225A3 among the plurality of light exit openings 225A in the pixel definition layer 225 is located in a region of the blue sub-pixel B, and light emitted by the light-emitting layer 223 of the blue sub-pixel B passes through the first light exit opening 225A3, so that the light-emitting region 221A of the blue sub-pixel B is obtained. The second light exit opening 225A2 among the plurality of light exit openings 225A in the pixel definition layer 225 is located in a region of the red sub-pixel R, and light emitted by the light-emitting layer 223 of the red sub-pixel R passes through the second light exit opening 225A2, so that the light-emitting region 221A of the red sub-pixel R is obtained. The third light exit opening 225A1 among the plurality of light exit openings 225A in the pixel definition layer 225 is located in a region of the green sub-pixel G, and light emitted by the light-emitting layer 223 of the green sub-pixel G passes through the third light exit opening 225A1, so that the light-emitting region 221A of the green sub-pixel G is obtained.

In this way, the opening area of the first light exit opening 225A3 is greater than the opening area of the second light exit opening 225A2, and the opening area of the second light exit opening 225A2 is greater than the opening area of the third light exit opening 225A1. Therefore, the area of the light-emitting region 221A of the blue sub-pixel B is greater than the area of the light-emitting region 221A of the red sub-pixel R, and the area of the light-emitting region 221A of the red sub-pixel R is greater than the area of the light-emitting region 221A of the green sub-pixel G.

Human eyes have different sensitivities to colors. The sensitivity of human eyes to colors is specifically: green>red>blue. In view of this, since the area of the light-emitting region 221A of the blue sub-pixel B is greater than the area of the light-emitting region 221A of the red sub-pixel R, and the area of the light-emitting region 221A of the red sub-pixel R is greater than the area of the light-emitting region 221A of the green sub-pixel G, it is possible to realize a balanced perception of light of various colors by the human eye, reduce redundancy of the sub-pixels, and improve the aperture ratio and resolution.

As shown in FIG. 18, some embodiments of the present disclosure further provide a display panel 900 including the display substrate 200 as described above and the touch structure 1000 as described above. The touch structure 1000 is disposed on the light exit side of the display substrate 200.

As shown in FIG. 10, the display substrate 200 includes a base 210, and light-emitting devices L that are formed on the base. The encapsulation layer 250 covers the light-emitting devices 240, and the touch structure 1000 is formed on the encapsulation layer 250. In some embodiments, when the light exit side of the display substrate 200 may also be provided with an anti-reflection structure (e.g., a circular polarizer), the touch structure 1000 is formed between the encapsulation layer 250 and the anti-reflection structure, and the metal mesh 100 may be directly formed on a surface of the encapsulation layer 250, that is, there is no other film layer between the metal mesh 100 and the surface of the encapsulation layer 250.

In some embodiments, as shown in FIG. 12, an orthogonal projection 221AT of a light-emitting region 221A of at least one sub-pixel 221 of the display substrate 200 on the base 210 of the display substrate 200 is located within an orthogonal projection 100AT of an opening 100A of the metal mesh 100 of the touch structure 1000 on the base 210 of the display substrate 200.

The shape of the orthogonal projection 221AT of the light-emitting region 221A of the sub-pixel 221 on the base 210 is the same or substantially the same as the shape of the light-emitting region 221A of the sub-pixel 221. Similarly, the shape of the opening 100A of the metal mesh 100 of the touch structure 1000 is the same or substantially the same as the shape of the orthogonal projection 100AT of the opening 100A of the metal mesh 100 of the touch structure 1000 on the base 210.

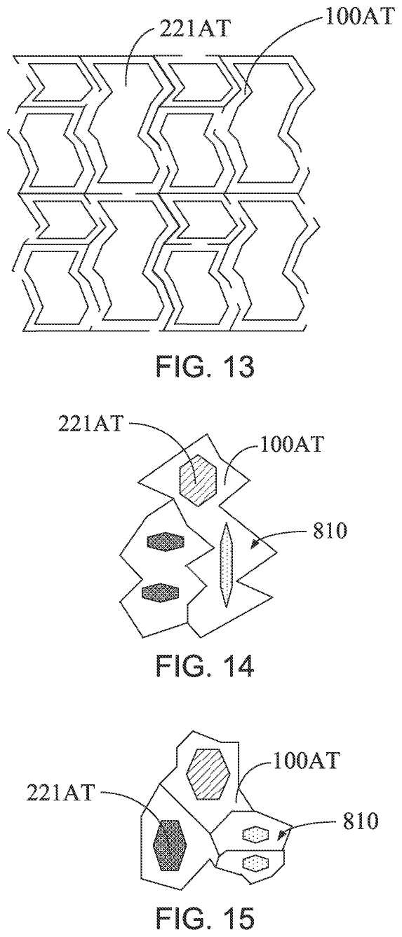

In the case where the opening 100A is as shown in FIG. 3, that is, in the case where at least one metal conductive line 110 among the plurality of metal conductive lines 110 included in the opening 100A includes at least one disconnected hole 110A, the orthogonal projection 221AT of the light-emitting region 221A of the sub-pixel 221 on the base 210 and the orthogonal projection 100AT of the opening 100A on the base 210 corresponding to FIG. 12 are shown in FIG. 13.

The orthogonal projection 221AT of the light-emitting region 221A of the at least one sub-pixel 221 on the base 210 is located within the orthogonal projection 100AT of the opening 100A of the metal mesh 100 on the base 210, which can be understood that the orthogonal projection of the light-emitting region 221A of the at least one sub-pixel 221 on the base 210 is located within at least a part of region of the orthogonal projection 100AT of the opening 100A of the metal mesh 100 on the base 210.

The orthogonal projection 221AT of the light-emitting region 221A of one sub-pixel 221 on the base 210 is located within the orthogonal projection 100AT of one opening 100A of the metal mesh 100 on the base 210; or, the orthogonal projections 221AT of the light-emitting regions 221A of multiple sub-pixels 221 on the base 210 are located within the orthogonal projection of one opening 100A of the metal mesh 100 on the base 210, as shown in FIG. 14; or, the orthogonal projections 221AT of the light-emitting regions 221A of multiple sub-pixels 221 on the base 210 are respectively located within the orthogonal projections 100AT of multiple openings 100A of the metal mesh 100 on the base 210, as shown in FIG. 15.

For example, the orthogonal projections 221AT of the light-emitting regions 221A of two sub-pixels 221 on the base 210 are both located within the orthogonal projection 100AT of one opening 100A of the metal mesh 100 on the base 210, as shown in FIG. 14; or, the orthogonal projections 221AT of the light-emitting regions 221A of four sub-pixels 221 on the base 210 are respectively located within the orthogonal projections 100AT of four openings 100A of the metal mesh 100 on the base, as shown in FIG. 15.

In addition, the orthogonal projections 221AT of the light-emitting regions 221A of some sub-pixels 221 on the base 210 may at least partially overlap with the orthogonal projections 100AT of multiple openings 100A of the metal mesh 100 on the base 210, respectively. That is, a part of the orthogonal projection 221AT of the light-emitting region 221A of the sub-pixel 221 on the base 210 at least partially overlaps with the orthogonal projection 100AT of an opening 100A of the metal mesh 100 on the base 210, and another part of the orthogonal projection 221AT of the light-emitting region 221A of the sub-pixel 221 on the base 210 at least partially overlaps with the orthogonal projection 100AT of another opening 100A of the metal mesh 100 on the base 210.

In some embodiments, the orthogonal projection 221AT of the light-emitting region 221A of each sub-pixel 221 on the base 210 is located within the orthogonal projection 100AT of an opening 100A of the metal mesh 100 on the base 210. That is, the orthogonal projection 221AT of the light-emitting region 221A of each sub-pixel 221 on the base 210 is located within at least a part of region of the orthogonal projection 100AT of an opening 100A of the metal mesh 100 on the base 210.

The number of openings 100A of the metal mesh 100 of the touch structure 1000 may be equal to the number of sub-pixels 221 of the display substrate 200. The positions of the plurality of sub-pixels 221 of the display substrate 200 are in one-to-one correspondence with the positions of the plurality of openings 100A of the metal mesh 100 of the touch structure 1000.

The shape of the orthogonal projection 221AT of the light-emitting region 221A of the sub-pixel 221 on the base 210 may be the same as or different from the shape of the orthogonal projection 100AT of the opening 100A of the metal mesh 100 on the base 210. For example, the shape of the orthogonal projection 221AT of the light-emitting region 221A of the sub-pixel 221 on the base 210 is a 7-sided structure, and the shape of the orthogonal projection 100AT of the opening 100A of the metal mesh 100 on the base 210 is a 9-sided structure; or, the shape of the orthogonal projection 221AT of the light-emitting region 221A of the sub-pixel 221 on the base 210 and the shape of the orthogonal projection 100AT of the opening 100A of the metal mesh 100 on the base 210 are two different 8-sided structures.

The orthogonal projection 221AT of the light-emitting region 221A of the sub-pixel 221 on the base 210 may be located in the central region of the orthogonal projection 100AT of the opening 100A of the metal mesh 100 on the base 210; or, the orthogonal projection 221AT of the light-emitting region 221A of the sub-pixel 221 on the base 210 may be located in the border region of the orthogonal projection 100AT of the opening 100A of the metal mesh 100 on the base 210.

The contour of the orthogonal projection 221AT of the light-emitting region 221A of the sub-pixel 221 on the base 210 may at least partially coincide with the contour of the orthogonal projection 100AT of the opening 100A of the metal mesh 100 on the base 210; or, the contour of the orthogonal projection 221AT of the light-emitting region 221A of the sub-pixel 221 on the base 210 may not coincide with the contour of the orthogonal projection 100AT of the opening 100A of the metal mesh 100 on the base 210, that is, the contour of the orthogonal projection 221AT of the light-emitting region 221A of the sub-pixel 221 on the base 210 and the contour of the orthogonal projection 100AT of the opening 100A of the metal mesh 100 on the base 210 have a gap 810 therebetween, as shown in FIGS. 12 to 16.

In the case where the shape of the orthogonal projection 221AT of the light-emitting region 221A of the sub-pixel 221 on the base 210 is different from the shape of the orthogonal projection 100AT of the opening 100A of the metal mesh 100 on the base 210, the gap 810 between the contour of the orthogonal projection 221AT of the light-emitting region 221A of the sub-pixel 221 on the base 210 and the contour of the orthogonal projection 100AT of the opening 100A of the metal mesh 100 on the base 210 may have different gap widths in different directions, as shown in FIGS. 14 to 16, the orthogonal projection 221AT of the light-emitting region 221A of the same sub-pixel 221 on the base 210 has different gap widths in different directions from the orthogonal projection 100AT of the opening 100A on the base 210.

In addition, in the case where the orthogonal projection 221AT of the light-emitting region 221A of the sub-pixel 221 on the base 210 is located in the border region of the orthogonal projection 100AT of the opening 100A of the metal mesh 100 on the base 210, the gap 810 between the contour of the orthogonal projection 221AT of the light-emitting region 221A of the sub-pixel 221 on the base 210 and the contour of the orthogonal projection 100AT of the opening 100A of the metal mesh 100 on the base 210 may have different gap widths in different directions.

In the case where the shape of the orthogonal projection 221AT of the light-emitting region 221A of the sub-pixel 221 on the base 210 is the same as the shape of the orthogonal projection 100AT of the opening 100A of the metal mesh 100 on the base 210, and the orthogonal projection 221AT of the light-emitting region 221A of the sub-pixel 221 on the base 210 is located in the central region of the orthogonal projection 100AT of the opening 100A of the metal mesh 100 on the base 210, the gap widths in different directions of the gap 810 between the contour of the orthogonal projection 221AT of the light-emitting region 221A of the sub-pixel 221 on the base 210 and the contour of the orthogonal projection 100AT of the opening 100A of the metal mesh 100 on the base 210 may be substantially the same, as shown in FIGS. 12 and 13.

The metal mesh 100 can match the structure of the conventional sub-pixel. Since the shape of the conventional sub-pixel is a symmetrical structure, the shape of the orthogonal projection 221AT of the light-emitting region 221A of the sub-pixel 221 on the base 210 is different from the shape of the orthogonal projection 100AT of the opening 100A of the metal mesh 100 on the base 210, as shown in FIGS. 14 to 16. The metal mesh 100 can also match the structure of the sub-pixel whose shape corresponds to the shape of the opening 100A. That is, the shape of the orthogonal projection 221AT of the light-emitting region 221A of the sub-pixel 221 on the base 210 is the same as the shape of the orthogonal projection 100AT of the opening 100A of the metal mesh 100 on the base 210, as shown in FIGS. 12 and 13.

In FIGS. 12 and 13, in the case where the gap widths in different directions of the gap 810 between the contour of the orthogonal projection 221AT of the light-emitting region 221A of the sub-pixel 221 on the base 210 and the contour of the orthogonal projection 100AT of the opening 100A of the metal mesh 100 on the base 210 can be substantially the same, the area of the pixel in the display panel 900 can be positively correlated with the area of the opening, and the aperture ratio and resolution can be improved.

In some embodiments, the contour of the orthogonal projection 221AT of the light-emitting region 221A of the at least one sub-pixel 221 on the base 210 and the contour of the orthogonal projection 100AT of the opening 100A on the base 210 have a gap 810 therebetween.

That is, the area of the orthogonal projection 221AT of the light-emitting region 221A of the sub-pixel 221 on the base 210 is less than the area of the orthogonal projection 100AT of the opening 100A on the base 210, and the contour of the orthogonal projection 221AT of the light-emitting region 221A of the sub-pixel 221 on the base 210 does not intersect with and is located within the contour of the orthogonal projection 100AT of the opening 100A on the base 210.

The orthogonal projection 221AT of the light-emitting region 221A of one sub-pixel 221 on the base 210 is located within the orthogonal projection 100AT of one opening 100A of the metal mesh 100 on the base 210, and the contour of the orthogonal projection 221AT of the light-emitting region 221A of the one sub-pixel 221 on the base 210 does not intersect with and is located within the contour of the orthogonal projection 100AT of the one opening 100A on the base 210.

Alternatively, the orthogonal projections 221AT of the light-emitting regions 221A of multiple sub-pixels 221 on the base 210 are located within the orthogonal projection 100AT of one opening 100A of the metal mesh 100 on the base 210, and the contours of the orthogonal projections 221AT of the light-emitting regions 221A of the multiple sub-pixels 221 on the base 210 do not intersect with each other, and do not intersect with and are located within the contour of the orthogonal projection 100AT of the one opening 100A on the base 210.

Alternatively, the orthogonal projections 221AT of the light-emitting regions 221A of multiple sub-pixels 221 on the base 210 are respectively located within the orthogonal projections 100AT of multiple openings 100A of the metal mesh 100 on the base 210, and the contour of the orthogonal projection 221AT of the light-emitting region 221A of each sub-pixel 221 on the base 210 does not intersect with and is located within the contour of the orthogonal projection 100AT of a corresponding opening 100A on the base 210.

The contour of the orthogonal projection 221AT of the light-emitting region 221A of one sub-pixel 221 on the base 210 and the contour of the orthogonal projection 100AT of one opening 100A on the base 210 have the gap 810 therebetween, so that light emitted by the sub-pixel 221 will not be blocked by the metal conductive lines 110 of the metal mesh 100 of the touch structure 1000 on the light exit side of the sub-pixel 221. As a result, it may be possible to reduce or eliminate the Mura phenomenon of the display panel caused by the metal conductive lines 110 blocking the light (the phenomenon of display of uneven brightness and display of various traces).

In some embodiments, as shown in FIG. 11, the display substrate 200 includes a plurality of pixel units 820, and each pixel unit 820 includes a plurality of sub-pixels 221. As shown in FIG. 1, the metal mesh 100 includes a plurality of opening units 120, and each opening unit 120 includes one or more openings 100A.

Orthogonal projections 221AT of light-emitting regions 221A of a plurality of sub-pixels 221 of a pixel unit 820 on the base 210 are located within orthogonal projections 100AT of one or more openings 100A of an opening unit 120 on the base 210.

The number of sub-pixels 221 in one pixel unit 820 may be 3, 4, 5 or 6, which is not limited here. Similarly, the number of openings 100A in one opening unit 120 may be 1, 3, 5 or 6, and the number of openings 100A in the opening unit 120 is not greater than the number of sub-pixels 221 in the pixel unit 820.

For example, the pixel unit 820 includes four sub-pixels 221, the opening unit 120 includes one opening 100A, and the orthogonal projection 100AT of the one opening 100A on the base 210 covers the orthogonal projections 221AT of the light-emitting regions 221A of the four sub-pixels 221 on the base 210.

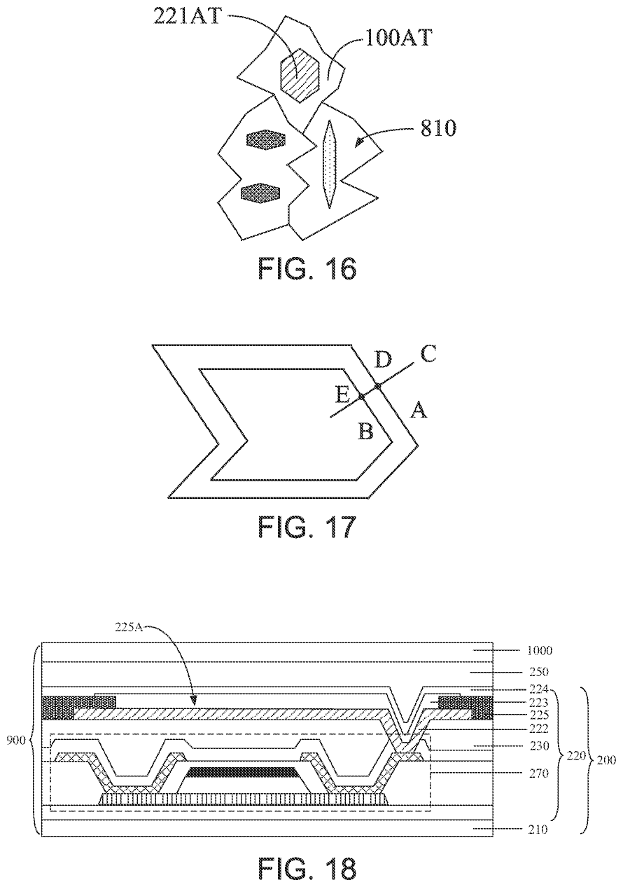

For example, the pixel unit 820 includes four sub-pixels 221, the opening unit 120 includes three openings 100A, the orthogonal projection 100AT of an opening 100A on the base 210 covers the orthogonal projection 221AT of the light-emitting region 221A of one sub-pixel 221 on the base 210, the orthogonal projection 100AT of another opening 100A on the base 210 covers the orthogonal projections 221AT of the light-emitting regions 221A of other two sub-pixels 221 on the base 210, and the orthogonal projection 100AT of the remaining one opening 100A on the base 210 covers the orthogonal projection 221AT of the light-emitting region 221A of the remaining one sub-pixel 221 on the base, as shown in FIG. 16.

In addition, the types of opening units 120 in the metal mesh 100 may vary, and different types of opening units 120 may also have different shapes of openings 100A and different numbers of openings 100A. Considering different types of opening units 120 with different numbers of openings 100A as an example, the pixel unit 820 includes four sub-pixels 221, the first type of opening unit 120 includes two openings 100A, and the second type of opening unit 120 includes four openings 100A. In this case, orthogonal projections of light-emitting regions 221A of four sub-pixels 221 in a pixel unit 820 on the base 210 are located within orthogonal projections 100AT of two openings 100A in the first type of opening unit 120 on the base, as shown in FIG. 14; and orthogonal projections 221AT of light-emitting regions 221A of four sub-pixels 221 in another pixel unit 820 on the base 210 are located within orthogonal projections 100AT of two openings 100A in the second type of opening unit 120 on the base 210, as shown in FIG. 15.

Orthogonal projections 221AT of light-emitting regions 221A of a plurality of sub-pixels 221 of a pixel unit 820 on the base 210 are located within orthogonal projections of one or more openings 100A of an opening unit 120 on the base 210, which can be understood that the positions of the pixel unit 820 and the opening unit 120 in the display panel correspond to each other. In this way, as for the arrangement of the plurality of opening units 120 in the touch structure 1000, reference can be made to the arrangement of the pixel units 820 in the display substrate 200.

In some embodiments, the pixel unit 820 includes multiple sub-pixels 221, the opening unit 120 includes one opening 100A, and orthogonal projections 221AT of light-emitting regions 221A of the multiple sub-pixels 221 on the base 210 are located within an orthogonal projection 100AT of the one opening 100A on the base 210.

For example, the pixel unit 820 includes five sub-pixels 221, the opening unit 120 includes one opening 100A, and orthogonal projections 221AT of light-emitting regions 221A of the five sub-pixels 221 in the same pixel unit 820 on the base 210 are all located within an orthogonal projection 100AT of the one opening 100A on the base 210.

In some embodiments, the pixel unit 820 includes multiple sub-pixels 221, and the opening unit 120 includes two openings 100A; an orthogonal projection 221AT of a light-emitting region 221A of at least one sub-pixel 221 on the base 210 is located within an orthogonal projection of one opening 100A on the base 210; and an orthogonal projection of a light-emitting region 221A of the remaining sub-pixel(s) 221 on the base 210 is located within an orthogonal projection 100AT of the other opening 100A on the base 210.

For example, the pixel unit 820 includes four sub-pixels 221, and the opening unit 120 includes two openings 100A. An orthogonal projection 100AT of one opening 100A on the base 210 covers an orthogonal projection 221AT of a light-emitting region 221A of one sub-pixel 221 on the base 210, and an orthogonal projection 100AT of the other opening 100A on the base 210 covers orthogonal projections 221AT of light-emitting regions 221A of the remaining three sub-pixels 221 on the base 210; alternatively, an orthogonal projection 100AT of one opening 100A on the base 210 covers orthogonal projections 221AT of light-emitting regions 221A of two sub-pixels 221 on the base 210, and an orthogonal projection 100AT of the other opening 100A on the base 210 covers orthogonal projections 221AT of light-emitting regions 221A of the remaining two sub-pixels 221 on the base 210, as shown in FIG. 14.

In some embodiments, the pixel unit 820 includes multiple sub-pixels 221, and the opening unit 120 includes three openings 100A; an orthogonal projection 221AT of a light-emitting region 221A of at least one sub-pixel 221 on the base 210 is located within an orthogonal projection of one of the openings 100A on the base 210; an orthogonal projection 221AT of a light-emitting region 221A of at least one sub-pixel 221 on the base 210 is located within an orthogonal projection of another one of the openings 100A on the base 210; and an orthogonal projection of a light-emitting region 221A of the remaining sub-pixel(s) 221 on the base 210 is located within an orthogonal projection 100AT of the remaining one of the openings 100A on the base 210.

For example, as shown in FIG. 16, the pixel unit 820 includes four sub-pixels 221, and the opening unit 120 includes three openings 100A. An orthogonal projection 100AT of one opening 100A on the base 210 covers an orthogonal projection 221AT of a light-emitting region 221A of one sub-pixel 221 on the base 210; an orthogonal projection 100AT of another opening 100A on the base 210 covers an orthogonal projection 221AT of a light-emitting region 221A of another sub-pixel 221 on the base 210; and an orthogonal projection 100AT of the remaining one opening 100A on the base 210 covers orthogonal projections 221AT of light-emitting regions 221A of the remaining two sub-pixels 221 on the base 210.

In some embodiments, the pixel unit 820 includes multiple sub-pixels 221, and the opening unit 120 includes four openings 100A; an orthogonal projection 221AT of a light-emitting region 221A of at least one sub-pixel 221 on the base 210 is located within an orthogonal projection of a first opening 100A on the base 210; an orthogonal projection 221AT of a light-emitting region 221A of at least one sub-pixel 221 on the base 210 is located within an orthogonal projection of a second opening 100A on the base 210; an orthogonal projection 221AT of a light-emitting region 221A of at least one sub-pixel 221 on the base 210 is located within an orthogonal projection of a third opening 100A on the base 210; and an orthogonal projection of a light-emitting region 221A of the remaining sub-pixel(s) 221 on the base 210 is located within an orthogonal projection 100AT of a fourth opening 100A on the base 210.

For example, as shown in FIG. 15, the pixel unit 820 includes four sub-pixels 221, and the opening unit 120 includes four openings 100A. An orthogonal projection 100AT of a first opening 100A on the base 210 covers an orthogonal projection 221AT of a light-emitting region 221A of one sub-pixel 221 on the base 210; an orthogonal projection 100AT of a second opening 100A on the base 210 covers an orthogonal projection 221AT of a light-emitting region 221A of another sub-pixel 221 on the base 210; an orthogonal projection 100AT of a third opening 100A on the base 210 covers an orthogonal projection 221AT of a light-emitting region 221A of yet another sub-pixel 221 on the base 210; and an orthogonal projection 100AT of a fourth opening 100A on the base 210 covers an orthogonal projection 221AT of a light-emitting region 221A of the remaining one sub-pixel 221 on the base 210.

In some embodiments, as shown in FIGS. 12 and 13, the pixel unit 820 includes sub-pixels 221 of X colors, the opening unit 120 includes openings 100A of X shapes, and the sub-pixels of X colors 221 are in one-to-one correspondence with the openings 100A of X shapes, X being an integer and X≥3.

A first orthogonal projection 100AT of an opening 100A of a target shape on the base 210 covers a second orthogonal projection 221AT of a light-emitting region 221A of a sub-pixel 221 of a target color on the base 210, the target shape is any one shape among the X shapes, the target color is a color corresponding to the target shape.

A shape of the first orthogonal projection 100AT is substantially the same as a shape of the second orthogonal projection 221AT, and a contour of the second orthogonal projection 221AT and a contour of the first orthogonal projection 100AT have a gap 810 therebetween.

The number of openings 100A in the opening unit 120 is equal to the number of sub-pixels 221 in the pixel unit 820, and opening(s) 100A of a shape in the opening unit 120 are in one-to-one correspondence with sub-pixel(s) 221 of a color in the pixel unit 820. The shapes of different openings 100A in the same opening unit 120 are different from each other.

A first orthogonal projection 100AT of an opening 100A of each shape on the base 210 covers a second orthogonal projection 221AT of a light-emitting region 221A of a sub-pixel 221 of a color corresponding to the opening 100A of the shape on the base 210.

For example, as shown in FIG. 12, the pixel unit 820 includes a blue sub-pixel B, a red sub-pixel R and a green sub-pixel G; as shown in FIG. 1, the opening unit 120 includes an opening 100A3 of a first shape corresponding to the blue sub-pixel B, an opening 100A2 of a second shape corresponding to the red sub-pixel R, and an opening 100A1 of a third shape corresponding to the green sub-pixel G. As shown in FIG. 12, a first orthogonal projection 100AT1 of the opening 100A3 of the first shape on the base 210 covers a second orthogonal projection 221AT3 of a light-emitting region 221A of the blue sub-pixel B on the base 210; a first orthogonal projection 100AT2 of the opening 100A2 of the second shape on the base 210 covers a second orthogonal projection 221AT2 of a light-emitting region 221A of the red sub-pixel R on the base 210; and a first orthogonal projection 100AT1 of the opening 100A1 of the third shape on the base 210 covers a second orthogonal projection 221AT1 of a light-emitting region 221A of the green sub-pixel G on the base 210.

The above example may be a case where there is one sub-pixel 221 of one color in the pixel unit 820, or a case where there are multiple sub-pixels 221 of one color in the pixel unit 820. For example, the pixel unit 820 includes two green sub-pixels 221, and the first orthogonal projection 100AT1 of the opening 100A1 of the third shape on the base 210 covers second orthogonal projections 221AT1 of light-emitting regions 221A of two green sub-pixels G on the base 210.

The shape of the first orthogonal projection 100AT is substantially the same as the shape of the second orthogonal projection 221AT. That is, the shape of the orthogonal projection 100AT of an opening 100A of one shape on the base 210 is substantially the same as the shape of the orthogonal projection 221AT of the light-emitting region 221A of a sub-pixel 221 of a color corresponding thereto on the base 210. It can be understood that a shape of an opening 100A is substantially the same as a shape of a sub-pixel 221 of a corresponding color. That is, not only are the shapes of the openings 100A in the opening unit 120 in one-to-one correspondence with the colors of the sub-pixels 221 in the pixel unit 820, but also the shape of the opening 100A is substantially the same as the shape of the sub-pixel 221 of the color corresponding to the opening 100A.

For example, the pixel unit 820 includes a blue sub-pixel 221 of a fourth shape, a red sub-pixel 221 of a fifth shape, and a green sub-pixel 221 of a sixth shape; the opening unit 120 includes an opening 100A of the fourth shape corresponding to the blue sub-pixel 221, an opening 100A of the fifth shape corresponding to the red sub-pixel 221, and an opening 100A of the sixth shape corresponding to the green sub-pixel 221.

There is a gap 810 between the contour of the second orthogonal projection 221AT and the contour of the first orthogonal projection 100AT. That is, for an opening 100A and a sub-pixel 221 with the same shape, an area of an orthogonal projection 100AT of the opening 100A on the base 210 is greater than an area of an orthogonal projection 221AT of the sub-pixel 221 on the base 210, and the contour of the orthogonal projection 221AT of the sub-pixel 221 on the base 210 does not intersect with and is located within the contour of the orthogonal projection 100AT of the opening 100A on the base 210.

There is a gap 810 between the contour of the orthogonal projection 221AT of the sub-pixel 221 on the base 210 and the contour of the orthogonal projection 100AT of the opening 100A on the base 210, thus preventing the metal conductive lines 110 enclosing the opening 100A from blocking the light emitted by the sub-pixel 221 on the light exit side of the sub-pixel 221 and ensuring the luminous efficiency of the display panel. Furthermore, the shape of the opening 100A is substantially the same as the shape of the sub-pixel 221. In this way, two contours of the same shape and nested with each other may achieve that the gap 810 has a uniform width in all directions. Thus, the production area of sub-pixels may be further expanded when the luminous efficiency of the display panel is ensured.

In some embodiments, a vertical distance between the contour of the first orthogonal projection 100AT and the contour of the second orthogonal projection 221AT (i.e., a width of the gap 810) is in a range from 8 μm to 12 μm. For example, the distance may be 9 μm, 10 μm, 10.3 μm, 11.1 μm, or 11.8 μm.

The above-mentioned vertical distance may refer to a linear distance between two intersection points where two parallel lines respectively belonging to two different contours and their perpendicular line intersect. For example, as shown in FIG. 17, the line A is a line of the contour of the first orthogonal projection 100AT, the line B is a line of the contour of the second orthogonal projection 221AT, the line C is a perpendicular line perpendicular to the line A and the line B, the point D is an intersection point of the line C and the line A, the point E is an intersection point of the line C and the line B, and the vertical distance between the line A and the line B is the linear distance between the point D and the point E.

As shown in FIGS. 19 and 20, the embodiments of the present disclosure further provide a touch display apparatus including the above display panel 900. Beneficial effects that can be achieved by the touch display apparatus are the same as the beneficial effects that can be achieved by the display panel 900 in the above embodiments, the structure of the touch display apparatus has been described above, and details will not be repeated here.

The foregoing descriptions are merely specific implementation manners of the present disclosure, but the protection scope of the present disclosure is not limited thereto, any changes or replacements that a person skilled in the art could conceive of within the technical scope of the present disclosure shall be included in the protection scope of the present disclosure. Therefore, the protection scope of the present disclosure shall be subject to the protection scope of the claims.

1. A touch structure, comprising:
a metal mesh including a plurality of metal conductive lines;
wherein the metal mesh has a plurality of openings, each opening is enclosed by metal conductive lines, and a shape of each opening is asymmetric.

2. The touch structure according to claim 1, wherein the opening is enclosed by N metal conductive lines that are connected end to end, and the N metal conductive lines have M different extension directions, N and M being integers, N≥5, and 3≤M≤N.

3. The touch structure according to claim 2, wherein any two metal conductive lines among the N metal conductive lines are asymmetrical to each other.

4. The touch structure according to claim 1, wherein the metal mesh comprises at least one type of opening, each type of opening includes a plurality of openings with the same shape, and different types of openings have different shapes.

5. The touch structure according to claim 1, wherein the metal mesh comprises a plurality of opening units, each opening unit comprising one or more openings, and at least one opening in the opening unit is enclosed by more than 8 metal conductive lines that are connected end to end.

6. The touch structure according to claim 5, wherein the opening unit includes at least three openings, and the at least three openings in the opening unit have different shapes and/or different areas.

7. The touch structure according to claim 1, wherein shapes of the metal conductive lines include a straight line segment and/or a curved line segment; and/or
the shape of the opening comprises at least one outwardly protruding convex angle and/or at least one inwardly protruding concave angle.

8. (canceled)

9. The touch structure according to claim 1, wherein a width of a metal conductive line is in a range from 1 μm to 20 μm; and/or
the metal conductive lines are made of copper, silver, nanocarbon or graphene.

10. (canceled)

11. The touch structure according to claim 1, wherein the touch structure comprises a plurality of touch electrodes, each touch electrode comprises a metal mesh, and the plurality of touch electrodes are configured to be independently connected to a touch chip;
or
the touch structure comprises: a plurality of driving units and a plurality of sensing units that are insulated from each other, and a first metal layer, an insulating layer and a second metal layer that are stacked in sequence; each driving unit comprises a plurality of driving electrodes arranged aide by side along a first direction and a first connection portion that electrically connects two adjacent driving electrodes; each sensing unit comprises a plurality of sensing electrodes arranged side by side along a second direction and a second connection portion that electrically connects two adjacent sensing electrodes, the first direction and the second direction intersecting; the insulating layer is provided therein with a plurality of via holes; the driving electrodes, the first connection portion and the sensing electrodes are located in one of the first metal layer and the second metal layer, the second connection portion is located in another of the first metal layer and the second metal layer, and the second connection portion electrically connects the two adjacent sensing electrodes through via holes; or, the driving electrodes, the second connection portion and the sensing electdoes are located in one of the first metal layer and the second metal layer, and the first connection portion is located in another of the first metal layer and the second metal layer, and the first connection portion electrically connects the two adjacent driving electrodes through via holes; and the driving electrodes, the sensing electrodes, the first connection portion and the second connection portion each comprise a metal mesh.

12. (canceled)

13. (canceled)

14. A display substrate, comprising
a base;
a display functional layer disposed on the base, wherein the display functional layer comprises a plurality of sub-pixels, and a shape of a light-emitting region of each sub-pixel is asymmetric.

15. The display substrate according to claim 14, wherein a contour of the light-emitting region is enclosed by N edges that are connected end to end, and the N edges have M different extension directions; N and M being integers, N≥5, and 3≤M≤N; or
a contour of the light-emitting region is enclosed by N edges that are connected end to end, the N edges have M different extension directions; N and M being integers, N≥5, 3≤M≤N, and any two edges among the N edges are asymmetrical to each other.

16. (canceled)

17. The display substrate according to claim 14, wherein the display functional layer comprises the sub-pixels of a plurality of colors, and a contour of a light-emitting region of a sub-pixel of at least one color is composed of more than 8 edges that are connected end to end; or
the display functional layer comprises the sub-pixels of a plurality of colors, a contour of a light-emitting region of a sub-pixel of at least one color is composed of more than 8 edges that are connected, end to end, and light-emitting regions of sub-pixels of different colors have different shapes and/or different areas.

18. (canceled)

19. The display substrate according to claim 14, wherein the display functional layer comprises:
a pixel definition layer provided therein with a plurality of light exit openings, wherein each light exit opening determines a light-emitting region of a sub-pixel, and a shape of the light exit opening is substantially the same as the shape of the light-emitting region of the sub-pixel.

20. The display substrate according to claim 19, wherein the display functional layer comprises a blue sub-pixel, a red sub-pixel and a green sub-pixel; an area of a light-emitting region of the blue sub-pixel is greater than an area of a light-emitting region of the red sub-pixel, and the area of the light-emitting region of the red sub-pixel is greater than an area of a light-emitting region of the green sub-pixel;
the pixel definition layer comprises a first light exit opening, a second light exit opening and a third light exit opening; the first light exit opening is configured to determine the light-emitting region of the blue sub-pixel, and the second light exit opening is configured to determine the light-emitting region of the red sub-pixel, and the third light exit opening is configured to determine the light-emitting region of the green sub-pixel; and
an opening area of the first light exit opening is greater than an opening area of the second light exit opening, and the opening area of the second light exit opening is greater than an opening area of the third light exit opening.

21. A display panel, comprising:
a display substrate comprising a base and a display functional layer disposed on the base, wherein the display functional layer comprises a plurality of sub-pixels, and a shape of a light-emitting region of each sub-pixel is asymmetric; and
the touch structure according to claim 1, the touch structure being disposed on a light exit side of the display substrate.

22. The display panel according to claim 21, wherein an orthogonal projection of a light-emitting region of at least one sub-pixel of the display substrate on the base of the display substrate is located within an orthogonal projection of an opening of the metal mesh of the touch structure on the base of the display substrate.

23. The display panel according to claim 22, wherein an orthogonal projection of the light-emitting region of each sub-pixel on the base is located within an orthogonal projection of an opening of the metal mesh on the base; or
a contour of the orthogonal projection of the light-emitting region of the at least one sub-pixel on the base and a contour of the orthogonal projection of the opening on the base have a gap therebetween.

24. (canceled)

25. The display panel according to claim 21, wherein the display substrate comprises a plurality of pixel units, and each pixel unit comprises a plurality of sub-pixels; the metal mesh comprises a plurality of opening units, and each opening unit comprises one or more openings; and
orthogonal projections of light-emitting regions of a plurality of sub-pixels of a pixel unit on the base are located within orthogonal projections of one or more openings of an opening unit on the base.

26. The display panel according to claim 25, wherein the pixel unit comprises a plurality of sub-pixel, and the opening unit comprises one opening; orthogonal projections of the plurality of sub-pixels in the pixel unit on the base are located within an orthogonal projection of the one opening on the base; or
the pixel unit comprises a plurality of sub-pixels, and the opening unit comprises two openings; an orthogonal projection of a light-emitting region of at least one sub-pixel in the pixel unit on the base is located within an orthogonal projection of one of the two openings on the base; and an orthogonal projection of a light-emitting region of a remaining sub-pixel on the base is located within an orthogonal projection of another of the two openings on the base.

27. The display panel according to claim 25, wherein the pixel unit comprises sub-pixels of X colors, the opening unit comprises openings of X shapes, and the sub-pixels of X colors and the openings of X shapes are in one-to-one correspondence, X being an integer and X≥3;
a first orthogonal projection of an opening of a target shape on the base covers a second orthogonal projection of a light-emitting region of a sub-pixel of a target color on the base;
the target shape is any one of the X shapes, and the target color is a color corresponding to the target shape; and
a shape of the first orthogonal projection is substantially the same as a shape of the second orthogonal projection, and a contour of the second orthogonal projection and a contour of the first orthogonal projection have a gap therebetween.

28. (canceled)
